(19) United States
(12) Patent Application Publication
(10) Pub. No.: US 2025/0207950 A1
(43) Pub. Date: Jun. 26, 2025

(54) CAPACITIVE SENSOR

(71) Applicant: The Research Foundation for The State University of New York, Binghamton, NY (US)

(72) Inventor: Ronald N. Miles, Newark Valley, NY (US)

(21) Appl. No.: 19/081,846

(22) Filed: Mar. 17, 2025

Related U.S. Application Data
(63) Continuation of application No. 17/058,102, filed on Nov. 23, 2020, now Pat. No. 12,253,391.
(60) Provisional application No. 62/676,058, filed on May 24, 2018.
(60) Provisional application No. 62/676,071, filed on May 24, 2018.

(51) Int. Cl. G01D 5/241; G01H 11/06; H03K 17/955; H04R 19/04

(52) U.S. Cl. CPC G01D 5/2412; G01H 11/06; H03K 17/955; H04R 19/04

(57) ABSTRACT

A dynamic capacitive sensor configuration is disclosed which imposes minimal force and resistance to motion on the moving electrode. Moving electrodes avoid adverse effects of large bias voltages such as pull-in instability, despite arbitrary levels of compliance. This configuration facilitates incorporation of highly compliant and thin electrode materials that present the least possible resistance to motion. This type of material is particularly useful for sensing sound. A large bias voltage can be applied without influencing its motion, e.g., 400 V. The electrical sensitivity to sound is high, e.g., approximately 0.5 volts/pascal, two orders of magnitude greater than typical acoustic sensors.

### CROSS-REFERENCES TO RELATED APPLICATIONS

This application is a continuation application of U.S. application Ser. No. 17/058,102, filed Nov. 23, 2020, entitled “Capacitive Sensor,” which is a U.S. national phase application based on International Application No. PCT/US2019/033855, filed on May 23, 2019, which claimed priority to U.S. Provisional Patent Application No. 62/676,058, filed May 24, 2018, and to U.S. Provisional Patent Application No. 62/676,071, filed May 24, 2018, the entire disclosures of which are hereby incorporated by reference. Priority benefit of these earlier filed applications is hereby claimed.

### FIELD OF THE INVENTION

The present technology relates to the field of capacitive sensors.

### BACKGROUND OF THE INVENTION

Sensors that rely on changes in capacitance are used in a very large number of important electronic products and systems. Capacitive sensors intended to detect motion or sound typically employ a lightweight, moveable electrode along with a fixed electrode. A bias voltage applied between these two electrodes enables the detection of changes in capacitance due to their relative motion. When detecting small motion, flow, or sound pressure, the performance of the sensor is normally improved when the effective stiffness between the moving and fixed electrodes is reduced. In sensitive microphones, the use of highly compliant moving electrodes having mass and stiffness as small as possible may be desired. In this situation, care must be taken in designing the capacitive electrodes to minimize the influence of electrostatic forces.

It is well-known that the design of capacitive motion sensors that use parallel plate capacitance require that the mechanical stiffness of the moving electrode be large enough to prevent collapse against the biasing electrode. This is because the electrostatic force acts as a negative stiffness for small motions about the static equilibrium position. If the bias voltage is high enough, the magnitude of this negative stiffness can exceed that of the mechanical stiffness, leading to instability. Other electrode designs can cause the electrostatic force to act as a positive stiffness which increases the overall system stiffness as the bias voltage is increased. In this case, an overly high bias voltage will lead to reduced response which reduces sensitivity. Responsivity measures the input-output gain of a detector system. Regardless of whether the electrostatic stiffness is positive or negative, it is nearly always true that the stiffness due to the electrostatic force has the effect of reducing the performance of the sensor.

If an electrostatic sensor has two electrodes, changes in the position of the moving electrode will typically result in a change in the electrostatic potential energy. The effective force applied by the electric field will be equal to the derivative of this potential energy with respect to the position of the moving electrode. To minimize the electrostatic force on the moving electrode, one may incorporate an additional fixed electrode such that the total potential energy of the system remains roughly constant with changes in the position of the moving electrode. While the total potential energy is nearly constant, resulting in a small electrostatic force and corresponding stiffness, the two fixed electrodes will experience dissimilar charges with changes in position of the moving electrode. Sensing these two fixed electrodes separately provides a sensor with greatly reduced influence of electrostatic forces on its motion.

In addition to seeking a design in which the total electrostatic potential energy remains roughly constant as the electrode moves, it is also desired to achieve absolute stability for large motions. This may be accomplished if the electrostatic force on the moving electrode always acts to restore it to its nominal equilibrium position for all possible motions.

Extremely thin, compliant materials are available for constructing these sensing electrodes, such as graphene [1], [2]. These structures have such low bending stiffness, however, that it is difficult to incorporate them into conventional microphone designs without their motion being strongly influenced by the electrostatic forces; their use in acoustic sensing requires new approaches to electrode design.

Highly compliant materials have shown considerable promise for acoustic sensing. Fine fibers such as spider silk have been found to very accurately represent the motion of air in a sound field [3], [4]. The challenges of incorporating highly compliant electrodes has motivated the creation of microphones that incorporate optical sensing [5]-[7]. While optical microphones do achieve the goal of preventing the designer from needing to consider the influence of the sensing mechanism on the forces applied to the mechanical elements, they have not yet proven competitive in high-volume, low-cost devices. The use of piezoelectric materials has also shown promise in avoiding the challenges of capacitive sensing for compliant microphone diaphragms [8]. It should also be mentioned that another motivation for avoiding the parallel plate capacitive sensing scheme is that the viscous damping caused by flow between the electrodes is a major source of thermal noise in miniature microphones [9].

FIGS. 1A-1D show conventional capacitive sensing schemes. FIG. 1A shows parallel plates separated by a gap that varies with acoustic pressure. FIG. 1B shows parallel plates separated by a gap, and shows overlap in a plane parallel to the plates varies with acoustic pressure. FIG. 1C shows a triplet of parallel plates, in which a distance between the central plate and the respective outer plates varies with acoustic pressure. FIG. 1D shows a triplet of parallel plates, in which one plate moves parallel to the plane of the plates in response to acoustic pressure, which causes differential overlap of the other two plates which are adjacent and coplanar, and separated by a gap.

There are, of course, countless electrode geometries that are possible in electrostatic sensing schemes. Depending on the amount of mass, stiffness and damping allowed in the moving electrode for the specific sensing application, existing approaches may achieve varying amounts of electrostatic force and stiffness. Four common configurations are shown in FIG. 1 [10]. The two shown on the left in FIGS. 1A and 1B, are composed of two electrodes and those on the right in FIGS. 1C and 1D contain three electrodes. In FIGS. 1A and 1C, the electrodes move transverse to their parallel planes, while in FIGS. 1B and 1D, the motion is parallel to the electrode planes. The configuration of FIG. 1A is by far the most common in acoustic sensors with the moving electrode comprising a pressure-sensing diaphragm. Each of these may be analyzed approximately using the well-known expression for the capacitance of parallel plates. This approximation assumes that the distance between plane surfaces is sufficiently small relative to all other dimensions so that the electric field is dominated by field lines that are straight and orthogonal to the plane surfaces.

The approximate expressions for the electrostatic potential energy, force, and effective stiffness for each of the four sensing configurations shown in FIGS. 1A-1D are considered. Assume that the second electrode in each panel shown is the moving electrode with the remaining electrodes held stationary. Let x be the displacement of the moving electrode relative to its nominal position. Each panel shows a cross section with the electrodes assumed to have constant cross section through the dimension, L, which is orthogonal to the plane of FIGS. 1A-1D. Also assume that electrode 2 is biased with a constant voltage, V₂, while the other electrodes are held at zero potential.

The potential energy of the configuration of FIG. 1A is

$${V}_{a} = \frac{1}{2} ϵ {V}_{2}^{2} \frac{WL}{d + x} \qquad ( 1 )$$

where ε=8.854 pF/m is the permittivity of the medium. The effective electrostatic force associated with the coordinate x, will be the derivative of Vₐ, evaluated at x, which we will assume is the equilibrium position [11],

$${f}_{a} = \frac{\partial }{\partial x} ( \frac{1}{2} ϵ {V}_{2}^{2} \frac{WL}{d + x} ) = - \frac{1}{2} ϵ {V}_{2}^{2} \frac{WL}{{( d + x )}^{2}} \qquad ( 2 )$$

This force always acts to pull the moving electrode toward the fixed electrode. For small perturbations about the equilibrium point x, this force will be proportional to the motion where the negative of this proportionality constant is the equivalent electrostatic stiffness, kₐ,

$${k}_{a} = - ϵ {V}_{2}^{2} \frac{WL}{{( d + x )}^{3}} \qquad ( 3 )$$

The electrostatic force in FIG. 1A is thus always negative for realizable values of x. This is the electrode configuration of nearly all pressure-sensing microphones.

A similar approach can be taken to estimate the electrostatic energy, force, and stiffness of the configuration shown in FIG. 1B,

$${V}_{b} = \frac{1}{2} ϵ {V}_{2}^{2} \frac{( W - x ) L}{d} \qquad ( 4 )$$

The effective electrostatic force is,

$${f}_{a} = \frac{\partial }{\partial x} ( \frac{1}{2} ϵ {V}_{2}^{2} \frac{( W - x ) L}{d + x} ) = - \frac{1}{2} ϵ {V}_{2}^{2} \frac{L}{d} \qquad ( 5 )$$

In this approximation, the force is independent of x and also acts to pull the moving electrode toward its nominal position. For this constant force, the effective stiffness is zero, k_{b}≈0. This configuration can be realized using interdigitated fingers or fins and has been successfully incorporated in some acoustic pressure sensors [12]. It should be noted that a more detailed electrostatic analysis of this configuration shows that when x is not small relative to W the electrostatic stiffness becomes positive [13]. While instability is avoided, the electrostatic force can impede the electrode motion.

The electrostatic potential energy of FIG. 1C is

$${V}_{c} = \frac{1}{2} ϵ {V}_{2}^{2} ( \frac{WL}{d + x} + \frac{WL}{d - x} ) \qquad ( 6 )$$

This expression depends on two terms, one that increases with x while the other decreases. The effective electrostatic force is,

$${f}_{c} = \frac{\partial }{\partial x} {V}_{c} = \frac{1}{2} ϵ {V}_{2}^{2} WL \frac{4 xd}{{( d + x )}^{2} {( d - x )}^{2}} \qquad ( 7 )$$

And the effective electrostatic stiffness is

$${k}_{c} = - \frac{\partial }{\partial x} {f}_{c} = - \frac{1}{2} ϵ {V}_{2}^{2} WL \frac{4 d}{{( d + x )}^{2} {( d - x )}^{2}} \qquad ( 8 )$$

In FIG. 1D, when x=0, we will assume that electrode 2 is centered over the intersection of the two fixed electrodes so that the overlap with each of them has width W/2. The electrostatic potential energy of the three electrode configuration in FIG. 1D is then

$${V}_{d} = \frac{1}{2} ϵ {V}_{2}^{2} WL ( \frac{( \frac{W}{2} - x )}{d} + \frac{( \frac{W}{2} + x )}{d} ) = \frac{1}{2} ϵ {V}_{2}^{2} \frac{WL}{d} \qquad ( 9 )$$

Because the energy is independent of x, the effective electro-static force and stiffness are zero, f_{d}=0, k_{d}=0. While this is highly desirable in a sensor, it is difficult to implement in a capacitive microphone. The electrode configuration presented in the following could be viewed as an attempt to realize an approximation to FIG. 1D in which the moving electrode is displaced in the direction normal to its plane rather than parallel to its plane as shown in FIG. 1D. Further analysis of the system is provided in Miles, R. N., “Notes on Electrostatics”, State University of New York, Binghamton, NY 13902-6000, which is expressly incorporated herein by reference in its entirety.

See, U.S. Pat. Nos. 3,931,469; 3,935,397; 3,941,946; 3,942,029; 3,944,756; 3,946,422; 3,958,662; 3,961,202; 3,980,838; 3,992,585; 4,006,317; 4,014,091; 4,034,332; 4,037,062; 4,046,974; 4,063,050; 4,081,626; 4,085,297; 4,093,884; 4,122,302; 4,149,095; 4,151,480; 4,160,882; 4,170,721; 4,188,513; 4,207,442; 4,215,249; 4,225,755; 4,246,448; 4,246,449; 4,249,043; 4,281,221; 4,288,735; 4,289,936; 4,302,634; 4,311,881; 4,323,736; 4,329,547; 4,360,955; 4,401,858; 4,403,117; 4,409,441; 4,414,433; 4,420,790; 4,429,189; 4,429,191; 4,429,192; 4,429,193; 4,434,327; 4,436,648; 4,439,641; 4,439,642; 4,461,931; 4,489,278; 4,491,697; 4,492,825; 4,515,997; 4,524,247; 4,533,795; 4,541,112; 4,542,264; 4,558,184; 4,567,445; 4,582,961; 4,615,105; 4,621,171; 4,764,690; 4,767,973; 4,790,021; 4,796,725; 4,802,227; 4,849,050; 4,849,071; 4,922,471; 4,977,590; 4,993,072; 5,014,322; 5,038,459; 5,054,081; 5,097,224; 5,161,128; 5,206,914; 5,208,789; 5,214,709; 5,335,210; 5,392,358; 5,452,268; 5,471,540; 5,490,220; 5,570,428; 5,573,679; 5,590,212; 5,600,610; 5,712,598; 5,745,438; 5,802,198; 5,854,846; 5,862,239; 5,870,482; 5,978,491; 6,075,867; 6,125,189; 6,145,186; 6,175,636; 6,178,249; 6,188,772; 6,201,874; 6,218,883; 6,243,474; 6,249,075; 6,304,662; 6,308,398; 6,343,129; 6,357,299; 6,366,678; 6,376,971; 6,393,129; 6,427,015; 6,434,245; 6,441,451; 6,449,370; 6,483,924; 6,493,288; 6,504,937; 6,510,231; 6,535,460; 6,535,612; 6,543,110; 6,545,384; 6,580,797; 6,583,533; 6,584,206; 6,600,825; 6,628,791; 6,630,639; 6,661,897; 6,664,718; 6,667,189; 6,677,176; 6,724,058; 6,731,766; 6,741,709; 6,744,896; 6,756,248; 6,760,455; 6,781,284; 6,785,393; 6,788,794; 6,788,795; 6,804,362; 6,806,593; 6,812,620; 6,812,624; 6,818,092; 6,819,769; 6,829,131; 6,842,964; 6,870,938; 6,870,939; 6,911,764; 6,940,211; 6,944,308; 6,978,029; 6,987,859; 7,003,127; 7,019,955; 7,023,066; 7,034,432; 7,039,202; 7,040,173; 7,049,732; 7,054,456; 7,062,055; 7,064,472; 7,074,634; 7,095,864; 7,107,665; 7,132,307; 7,142,684; 7,146,016; 7,152,481; 7,158,646; 7,193,256; 7,194,095; 7,199,501; 7,208,996; 7,215,527; 7,218,742; 7,221,768; 7,224,106; 7,233,097; 7,233,679; 7,256,927; 7,259,503; 7,269,267; 7,269,268; 7,292,700; 7,295,675; 7,298,856; 7,305,096; 7,317,234; 7,320,457; 7,327,851; 7,329,933; 7,346,178; 7,352,876; 7,359,286; 7,362,032; 7,362,873; 7,368,862; 7,377,175; 7,386,136; 7,394,182; 7,400,737; 7,425,749; 7,447,326; 7,461,281; 7,466,835; 7,468,575; 7,489,791; 7,493,821; 7,570,773; 7,579,678; 7,585,743; 7,595,580; 7,607,355; 7,608,989; 7,620,197; 7,642,575; 7,668,323; 7,697,899; 7,702,118; 7,702,124; 7,710,371; 7,715,583; 7,756,279; 7,761,981; 7,769,193; 7,781,249; 7,804,968; 7,804,969; 7,804,971; 7,805,821; 7,812,418; 7,829,366; 7,835,533; 7,848,532; 7,855,095; 7,856,804; 7,860,258; 7,880,565; 7,884,467; 7,888,840; 7,889,882; 7,894,616; 7,898,159; 7,899,196; 7,903,831; 7,907,743; 7,911,115; 7,912,235; 7,912,236; 7,916,879; 7,923,064; 7,923,902; 7,925,033; 7,925,221; 7,932,117; 7,940,944; 7,948,731; 7,949,142; 7,951,636; 7,953,235; 7,970,154; 7,974,430; 8,000,483; 8,004,373; 8,005,242; 8,009,838; 8,018,301; 8,023,667; 8,036,401; 8,041,059; 8,042,264; 8,045,733; 8,045,734; 8,047,995; 8,054,566; 8,059,837; 8,059,838; 8,059,842; 8,064,620; 8,072,010; 8,073,166; 8,073,167; 8,073,179; 8,080,835; 8,081,784; 8,085,956; 8,085,965; 8,090,125; 8,093,783; 8,094,839; 8,094,841; 8,094,844; 8,098,853; 8,098,855; 8,103,039; 8,104,354; 8,107,651; 8,111,847; 8,111,871; 8,114,700; 8,126,166; 8,126,167; 8,126,171; 8,130,986; 8,134,375; 8,138,034; 8,139,762; 8,139,790; 8,139,794; 8,165,323; 8,170,237; 8,175,293; 8,175,294; 8,183,739; 8,184,832; 8,188,557; 8,194,908; 8,196,282; 8,199,939; 8,218,794; 8,229,140; 8,242,840; 8,243,962; 8,243,966; 8,254,598; 8,259,963; 8,265,287; 8,284,967; 8,295,514; 8,295,528; 8,300,858; 8,300,860; 8,327,521; 8,327,711; 8,335,328; 8,345,898; 8,345,910; 8,369,545; 8,369,552; 8,374,363; 8,379,890; 8,385,570; 8,385,586; 8,389,349; 8,391,520; 8,401,217; 8,401,513; 8,405,449; 8,406,437; 8,411,882; 8,416,973; 8,433,084; 8,438,710; 8,447,049; 8,448,326; 8,456,958; 8,467,550; 8,467,559; 8,468,665; 8,497,149; 8,502,329; 8,503,702; 8,508,109; 8,509,459; 8,515,100; 8,519,492; 8,526,656; 8,542,850; 8,542,852; 8,542,853; 8,546,170; 8,548,178; 8,553,913; 8,559,660; 8,562,565; 8,565,452; 8,565,454; 8,582,787; 8,588,433; 8,588,438; 8,588,451; 8,590,136; 8,594,349; 8,600,083; 8,605,919; 8,611,566; 8,618,718; 8,625,809; 8,625,823; 8,625,824; 8,625,825; 8,630,429; 8,630,430; 8,637,945; 8,638,249; 8,643,129; 8,643,382; 8,644,529; 8,664,733; 8,666,094; 8,666,095; 8,666,097; 8,670,581; 8,673,732; 8,675,895; 8,686,519; 8,692,340; 8,698,255; 8,698,256; 8,699,726; 8,699,728; 8,699,740; 8,705,767; 8,705,775; 8,710,601; 8,718,297; 8,723,277; 8,724,832; 8,731,220; 8,737,646; 8,742,517; 8,744,117; 8,755,539; 8,755,541; 8,755,556; 8,758,253; 8,760,031; 8,767,980; 8,774,428; 8,783,113; 8,787,600; 8,787,601; 8,790,567; 8,792,658; 8,803,261; 8,804,982; 8,811,635; 8,818,007; 8,824,706; 8,824,707; 8,824,713; 8,831,246; 8,836,111; 8,837,754; 8,842,858; 8,847,289; 8,848,950; 8,855,335; 8,855,337; 8,860,154; 8,861,764; 8,873,777; 8,885,853; 8,897,465; 8,913,762; 8,921,957; 8,929,584; 8,942,389; 8,942,394; 8,958,574; 8,958,581; 8,962,368; 8,965,008; 8,965,013; 8,965,027; 8,975,791; 8,975,984; 8,976,997; 8,983,090; 8,983,097; 8,983,099; 8,988,911; 8,995,690; 9,001,622; 9,002,037; 9,002,043; 9,008,332; 9,008,336; 9,008,344; 9,031,266; 9,042,578; 9,056,760; 9,059,630; 9,061,318; 9,071,694; 9,078,069; 9,083,286; 9,083,288; 9,084,366; 9,085,012; 9,094,110; 9,094,111; 9,094,112; 9,094,764; 9,096,424; 9,107,008; 9,111,548; 9,113,260; 9,113,263; 9,124,220; 9,128,136; 9,131,319; 9,133,016; 9,139,418; 9,143,869; 9,143,870; 9,143,876; 9,148,712; 9,148,726; 9,148,729; 9,148,730; 9,154,886; 9,161,113; 9,167,354; 9,170,164; 9,179,221; 9,181,080; 9,181,086; 9,197,967; 9,204,224; 9,210,516; 9,212,046; 9,214,151; 9,215,532; 9,216,897; 9,219,963; 9,221,675; 9,226,079; 9,232,317; 9,236,837; 9,241,205; 9,242,275; 9,247,331; 9,250,142; 9,253,579; 9,258,651; 9,258,660; 9,264,815; 9,266,713; 9,270,238; 9,271,067; 9,277,327; 9,277,329; 9,281,744; 9,282,389; 9,282,415; 9,287,834; 9,288,583; 9,290,375; 9,294,847; 9,301,036; 9,301,055; 9,319,765; 9,319,772; 9,321,626; 9,327,967; 9,332,332; 9,332,342; 9,332,345; 9,337,722; 9,338,557; 9,338,559; 9,340,413; 9,342,179; 9,344,805; 9,344,807; 9,344,808; 9,344,809; 9,344,810; 9,350,305; 9,351,062; 9,351,074; 9,351,083; 9,357,294; 9,357,296; 9,363,610; 9,369,804; 9,369,810; 9,382,109; 9,392,359; 9,402,137; 9,403,670; 9,407,991; 9,408,555; 9,413,317; 9,414,175; 9,419,562; 9,420,365; 9,420,380; 9,420,391; 9,426,563; 9,428,379; 9,438,979; 9,439,002; 9,444,928; 9,445,173; 9,445,188; 9,451,359; 9,455,671; 9,456,283; 9,462,364; 9,462,395; 9,466,277; 9,467,774; 9,470,710; 9,470,910; 9,479,875; 9,488,541; 9,491,531; 9,497,552; 9,499,395; 9,502,019; 9,503,814; 9,503,820; 9,503,821; 9,503,823; 9,510,108; 9,510,121; 9,516,415; 9,516,420; 9,516,425; 9,516,428; 9,518,884; 9,520,505; 9,521,492; 9,525,925; 9,537,359; 9,538,273; 9,540,226; 9,544,672; 9,544,697; 9,548,632; 9,548,655; 9,554,212; 9,554,213; 9,559,647; 9,560,454; 9,571,931; 9,575,116; 9,578,424; 9,584,924; 9,584,941; 9,590,570; 9,591,408; 9,591,417; 9,596,995; 9,602,921; 9,602,924; 9,609,429; 9,609,432; 9,609,764; 9,611,135; 9,615,167; 9,628,886; 9,628,909; 9,628,920; 9,634,628; 9,635,460; 9,641,949; 9,648,433; 9,654,071; 9,658,179; 9,661,411; 9,661,423; 9,667,173; 9,668,047; 9,668,056; 9,668,062; 9,673,768; 9,673,785; 9,674,627; 9,676,615; 9,676,617; 9,681,229; 9,681,243; 9,685,254; 9,686,617; 9,686,618; 9,692,372; 9,693,135; 9,695,038; 9,706,294; 9,706,312; 9,706,618; 9,708,174; 9,712,923; 9,716,945; 9,722,563; 9,723,423; 9,729,014; 9,729,114; 9,729,988; 9,736,586; 9,736,594; 9,738,514; 9,743,167; 9,743,191; 9,743,196; 9,743,203; 9,756,159; 9,756,430; 9,762,188; 9,769,573; 9,774,969; 9,778,302; 9,781,518; 9,787,142; 9,790,087; 9,791,341; 9,793,764; 9,794,661; 9,794,711; 9,800,212; 9,800,980; 9,809,444; 9,809,448; 9,809,451; 9,812,906; 9,813,831; 9,815,685; 9,820,056; 9,825,492; 9,828,236; 9,828,237; 9,831,723; 9,832,573; 9,838,767; 9,843,862; 9,854,360; 9,854,367; 9,860,649; 9,866,938; 9,866,959; 9,866,972; 9,877,106; 9,878,901; 9,893,691; 9,894,437; 9,900,707; 9,906,869; 9,919,913; 9,921,114; 9,929,603; 9,930,451; 9,936,304; 9,941,817; 9,942,666; 9,944,514; 9,947,858; 9,949,023; 9,949,025; 9,949,037; 9,955,269; 9,955,273; 9,961,440; 9,961,451; 9,966,090; 9,967,677; 9,967,678; 9,967,679; 20010002865; 20010005032; 20010033670; 20010046306; 20020034312; 20020048220; 20020067663; 20020076069; 20020076076; 20020093038; 20020118850; 20020122561; 20020127760; 20020141606; 20020172387; 20030016839; 20030021425; 20030021432; 20030034536; 20030057068; 20030063762; 20030068055; 20030118203; 20030123683; 20030128847; 20030133588; 20030137021; 20030174850; 20030210799; 20040062405; 20040088851; 20040113153; 20040179705; 20040179706; 20040179709; 20040184633; 20040252858; 20050002536; 20050005421; 20050013455; 20050058298; 20050061770; 20050069164; 20050094832; 20050123155; 20050196010; 20050207596; 20050254671; 20050254679; 20050259835; 20050262947; 20060008097; 20060008098; 20060072770; 20060078137; 20060078148; 20060093170; 20060093171; 20060131163; 20060177083; 20060210106; 20060215858; 20060227984; 20060230835; 20060233400; 20060233401; 20060256981; 20060280319; 20060284516; 20060285707; 20070003082; 20070009111; 20070023851; 20070056377; 20070057603; 20070058825; 20070058826; 20070075956; 20070076904; 20070108541; 20070113664; 20070116305; 20070121967; 20070121972; 20070140514; 20070154040; 20070160248; 20070182002; 20070189559; 20070193354; 20070201709; 20070201710; 20070230721; 20070242844; 20070274544; 20070284682; 20070286438; 20070297631; 20080006093; 20080019543; 20080031476; 20080042223; 20080047128; 20080075193; 20080075306; 20080083961; 20080089536; 20080104825; 20080123242; 20080123876; 20080123878; 20080164888; 20080175418; 20080190203; 20080192962; 20080203560; 20080204379; 20080205668; 20080212807; 20080229840; 20080247573; 20080285784; 20090003629; 20090003630; 20090016550; 20090022341; 20090050989; 20090060230; 20090060232; 20090067659; 20090087002; 20090087009; 20090090190; 20090130783; 20090136064; 20090154729; 20090161886; 20090161890; 20090169035; 20090185700; 20090190782; 20090202083; 20090208037; 20090214049; 20090214061; 20090214062; 20090218642; 20090232336; 20090243058; 20090252351; 20090262958; 20090278217; 20090285414; 20090316935; 20100013501; 20100072561; 20100084721; 20100098284; 20100119088; 20100142742; 20100142744; 20100155864; 20100158279; 20100158280; 20100166227; 20100166228; 20100177846; 20100177922; 20100208919; 20100212432; 20100219839; 20100254561; 20100277229; 20100284553; 20100315272; 20100328836; 20100329487; 20110003614; 20110019845; 20110026739; 20110038493; 20110038497; 20110045616; 20110073967; 20110075865; 20110089504; 20110090009; 20110108838; 20110110536; 20110123043; 20110131794; 20110135122; 20110154905; 20110163615; 20110170714; 20110170735; 20110182150; 20110200212; 20110222713; 20110228954; 20110228957; 20110255228; 20110303994; 20120014543; 20120017693; 20120033832; 20120043974; 20120056282; 20120076322; 20120076329; 20120091544; 20120091545; 20120099753; 20120104898; 20120106769; 20120121106; 20120133005; 20120140956; 20120153771; 20120170777; 20120213390; 20120217171; 20120223770; 20120224722; 20120224726; 20120230522; 20120250897; 20120250910; 20120260500; 20120269363; 20120294464; 20120299130; 20120319174; 20120321111; 20120326249; 20120328132; 20130010990; 20130010996; 20130016859; 20130028450; 20130028459; 20130032936; 20130044899; 20130051582; 20130051583; 20130051586; 20130051587; 20130062710; 20130070940; 20130089222; 20130108074; 20130109990; 20130119492; 20130121523; 20130129117; 20130129119; 20130129133; 20130156234; 20130160554; 20130170673; 20130177180; 20130195291; 20130208915; 20130221453; 20130221457; 20130223023; 20130223654; 20130230183; 20130233078; 20130256816; 20130271307; 20130277776; 20130279738; 20130287231; 20130334627; 20140003609; 20140010384; 20140013581; 20140037113; 20140037121; 20140038335; 20140072150; 20140072152; 20140079277; 20140086433; 20140090884; 20140105428; 20140109680; 20140119573; 20140126762; 20140132294; 20140133685; 20140137668; 20140140538; 20140140560; 20140145276; 20140191344; 20140225205; 20140226846; 20140233784; 20140239352; 20140247954; 20140264652; 20140266260; 20140266263; 20140270204; 20140270271; 20140270273; 20140270312; 20140286509; 20140291781; 20140294218; 20140299949; 20140301571; 20140301572; 20140307885; 20140307909; 20140318395; 20140341402; 20140369530; 20140376749; 20150001647; 20150003643; 20150003646; 20150003660; 20150010174; 20150014797; 20150016635; 20150023529; 20150031160; 20150035091; 20150049886; 20150055799; 20150061458; 20150063608; 20150071466; 20150078587; 20150078589; 20150078592; 20150082917; 20150088008; 20150102435; 20150110333; 20150125003; 20150131820; 20150137834; 20150139453; 20150162883; 20150163594; 20150181352; 20150189443; 20150189446; 20150202656; 20150208176; 20150228265; 20150230010; 20150230027; 20150245123; 20150256913; 20150256914; 20150264465; 20150264498; 20150271586; 20150289046; 20150296303; 20150304777; 20150311870; 20150318829; 20150319538; 20150326978; 20150336790; 20150341720; 20150341721; 20150350760; 20150373446; 20150380636; 20150381078; 20150381782; 20150382091; 20160014521; 20160014528; 20160014529; 20160029110; 20160029126; 20160029129; 20160037257; 20160037263; 20160041211; 20160044396; 20160050475; 20160057532; 20160065152; 20160066099; 20160073212; 20160087606; 20160091378; 20160105748; 20160107884; 20160111954; 20160134967; 20160134973; 20160142829; 20160149542; 20160155532; 20160156319; 20160157017; 20160157022; 20160157025; 20160165355; 20160165356; 20160167946; 20160173967; 20160173992; 20160173993; 20160173994; 20160176704; 20160182989; 20160183008; 20160192084; 20160192086; 20160192511; 20160218688; 20160219374; 20160219378; 20160221822; 20160241958; 20160241965; 20160255441; 20160255442; 20160277844; 20160295333; 20160304337; 20160309264; 20160330550; 20160336013; 20160337751; 20160340173; 20160344360; 20160345097; 20160352294; 20160360304; 20160360322; 20160362292; 20160373864; 20160373874; 20160377569; 20170034634; 20170041708; 20170041716; 20170048634; 20170059433; 20170064449; 20170070816; 20170078798; 20170078801; 20170094436; 20170099549; 20170102276; 20170127189; 20170135592; 20170142519; 20170142525; 20170155365; 20170156002; 20170160337; 20170164105; 20170164119; 20170166437; 20170180853; 20170180864; 20170180900; 20170195788; 20170215006; 20170217765; 20170223450; 20170230750; 20170238108; 20170245035; 20170245059; 20170245061; 20170247248; 20170251302; 20170251303; 20170257093; 20170260044; 20170265005; 20170265009; 20170275152; 20170280237; 20170280263; 20170284825; 20170289678; 20170318385; 20170318393; 20170318394; 20170332178; 20170355594; 20170363493; 20170366898; 20170374469; 20180002159; 20180002160; 20180002161; 20180002167; 20180002168; 20180007474; 20180012588; 20180027338; 20180035206; 20180035228; 20180035229; 20180044167; 20180050900; 20180059708; 20180062588; 20180063644; 20180066980; 20180067005; 20180077499; 20180091900; 20180091903; 20180091906; 20180103325; 20180103326; and RE40860 each of which is expressly incorporated herein by reference in its entirety.

### SUMMARY OF THE INVENTION

A dynamic capacitive sensor configuration is provided that is intended to impose minimal force and resistance to motion on the moving electrode. The aim is to enable the use of moving electrodes having arbitrary levels of compliance without suffering the adverse effects of large bias voltages such as pull-in instability. This configuration facilitates incorporation of highly compliant and thin electrode materials that present the least possible resistance to motion. This type of material is particularly useful for sensing sound. Measured results show that for the highly compliant acoustic sensor design examined here, a large bias voltage of 400 volts can be applied without influencing its motion. The electrical sensitivity to sound is found to be approximately 0.5 volts/pascal, two orders of magnitude greater than typical acoustic sensors.

One aspect of the present technology seeks to provide electrode designs for capacitive sensors that can minimize the effects of electrostatic stiffness on the microphone performance. If this can be accomplished, the moving electrode can be designed for maximum performance without being limited by constraints resulting from electrostatic forces.

Another aspect of the present technology seeks to provide electrode designs which are stable under all operating conditions. The electrode arrangement described herein achieves the goals of maintaining nearly constant potential energy and guaranteed stability.

A further aspect of the present technology provides a microphone design where a moving, sensing electrode has as little mechanical stiffness and mass as possible in order to properly respond to the minute pressure and air velocity fluctuations in a sound field.

The present approach follows from previous work on repulsive electrostatic actuators and sensors [14], [15]. These designs used an electrode configuration that permits the moving and sensing electrodes to move apart as the bias voltage is increased, rather than move toward each other as in the ubiquitous parallel plate configuration. While repulsive electrostatic devices avoid pull-in instability, it remains challenging to achieve an electrode design that doesn't suffer from electro-static stiffening, which limits the achievable performance.

In the following, a lightweight, compliant capacitive electrode configuration is provided that is intended to respond readily to acoustic pressure.

The preferred embodiment is a microphone, wherein the moving element responds to changes in air pressure or air flow, and the position of the moving element is sensed. However, the sensor design is not limited to microphones, and is more generally useful as an accelerometer, MEMS gyroscope, displacement sensor, vibrometer, shock sensor, etc. Further, while the basic design provides a pair of fixed electrodes maintained at virtual ground by a negative feedback transimpedance amplifier, this is not a limit of the technology. For example, if the voltage potential of one of the electrode surfaces is maintained at a different voltage than the other, the electric field experienced by the charged moving element will then be asymmetric, and rather than a normal force that acts parallel to the elongated axis of the element, a displacement forced will exist. Thus, the charged element will act as an actuator, for example of a digital mirror device, with analog control over displacement, and feedback control to maintain position. This same implementation also produces an output responsive to displacement of the charged element from its deflected position. Because the electrostatic forces on an inclined element are interactive with the effective stiffness of the sensor moving element, the result is a sensor whose sensitivity is controllable, dependent on the imbalance of the electrodes and the voltage potential of the charged element.

In another embodiment, the moving element is intentionally oscillated by a time-varying electrostatic field developed by the electrodes. For example, a chemi-selective sensor is possible if the diaphragm or fiber is coated with a chemi-specific material. As a species of interest is absorbed on the moving element, its mass changes, and this in turn alters its response to the oscillating electric field.

In a further embodiment, the moving element is thermally responsive, and for example changes in mechanical properties or dimensions. This in turn will alter the frequency and/or linear or non-linear response of the charged element to a perturbation, such as an oscillating electric field.

The repositioning of the nominal state of the moving charged element may also affect other sensor properties. For example, the charged element may be situated in an inhomogeneous medium. Therefore, a movement of the charged element will result in a different environment of operation.

In some cases, more than three electrodes may interact with a single moving element. In the case of a diaphragm, this may induce or sense twist. In the case of a fiber or filament, of other structure suspended for movement along two axes, the larger number of electrodes may detect the various axes of movement.

In some cases, more than one moving element is provided. These may interact with the electrodes and each other in various ways. For example, these can sense movement or effects along different axes (multi-axis sensor), and detect or process spatial variations in an exciting condition.

In some cases, the sensor can operate in a liquid medium. In the case of an electrostatic sensor, this typically implies a high dielectric liquid, in some cases it is possible to employ ionic liquids or low dielectric liquids, including water. For example, if the device according to the present technology is immersed in water, and the voltage potentials maintained below the hydrolysis potential of water, the result is that there will be a leakage current from the charged element to the electrodes resulting from the natural pKa (pH) of water, ˜10⁻⁷. This amount of ionization does not disqualify the embodiment. Other liquids have lower leakage. For example, mineral oil, hydrocarbons, silicones, hydrofluorocarbons, cryogenic liquefied gasses, etc.

In another embodiment, the presumption of no elongation of the charged element due to voltage potential with respect to the electrodes is not strictly valid. Therefore, the length of the element, and its distance from the electrodes, will vary with applied voltage. Typically, one does not wish the sensor to experience pull-in, but in specific sensor types, this is exactly the effect sought, since it locks the moving element in place.

Other modifications of the basic system are also possible. The following patents and published patent applications, each of which is expressly incorporated herein by reference in its entirety, disclose various implementation technologies, applications, and contexts in which the sensing technology according to the present technology may be implemented: See, U.S. Pat. Nos. 5,948,981; 6,104,492; 6,312,393; 6,360,601; 6,480,645; 6,529,652; 6,544,193; 6,549,692; 6,591,029; 6,625,399; 6,642,067; 6,745,627; 6,768,181; 6,784,500; 6,798,796; 6,847,036; 7,041,063; 7,054,519; 7,091,715; 7,100,446; 7,123,111; 7,157,712; 7,159,441; 7,208,729; 7,212,487; 7,214,298; 7,260,980; 7,275,433; 7,282,709; 7,284,430; 7,286,743; 7,294,503; 7,305,880; 7,308,827; 7,351,376; 7,403,805; 7,421,898; 7,448,995; 7,469,834; 7,481,111; 7,482,589; 7,485,100; 7,521,257; 7,622,081; 7,640,803; 7,652,752; 7,654,957; 7,714,278; 7,756,559; 7,791,027; 7,804,374; 7,809,417; 7,818,871; 7,822,510; 7,826,629; 7,827,864; 7,836,765; 7,939,021; 7,990,539; 8,022,779; 8,037,756; 8,051,698; 8,061,201; 8,129,176; 8,136,385; 8,164,588; 8,193,869; 8,220,318; 8,226,236; 8,252,539; 8,257,666; 8,263,336; 8,319,177; 8,322,213; 8,333,112; 8,339,014; 8,367,426; 8,391,517; 8,427,249; 8,427,657; 8,445,210; 8,451,068; 8,461,936; 8,482,300; 8,488,973; 8,556,428; 8,580,597; 8,586,918; 8,592,153; 8,592,154; 8,592,215; 8,627,511; 8,650,955; 8,658,367; 8,658,368; 8,669,771; 8,677,821; 8,686,802; 8,698,212; 8,742,469; 8,742,770; 8,746,039; 8,746,048; 8,748,947; 8,766,327; 8,774,885; 8,776,573; 8,787,117; 8,793,811; 8,800,369; 8,822,205; 8,822,906; 8,844,340; 8,875,576; 8,912,580; 8,914,089; 8,928,203; 8,953,414; 8,994,076; 8,994,954; 9,072,429; 9,146,109; 9,182,454; 9,200,887; 9,209,746; 9,217,641; 9,233,395; 9,238,250; 9,267,923; 9,270,281; 9,372,154; 9,389,079; 9,395,317; 9,411,000; 9,423,254; 9,448,069; 9,515,676; 9,535,137; 9,575,089; 9,611,139; 9,618,475; 9,618,533; 9,638,617; 9,645,166; 9,658,247; 9,668,035; 9,680,414; 9,702,992; 9,719,847; 9,740,003; 9,774,276; 9,778,282; 9,780,435; 9,800,019; 9,804,264; 9,810,775; 9,810,786; 9,812,838; 9,823,353; 9,857,468; 9,864,846; 9,869,754; 9,874,635; 9,905,992; 9,910,061; 9,910,062; 9,915,520; 9,927,393; 9,944,981; 9,958,414; 9,958,415; 9,958,545; 9,966,966; 20020049389; 20020068370; 20030033850; 20030071686; 20030139687; 20030142934; 20030179791; 20030196489; 20040039297; 20040039298; 20040060355; 20040237626; 20050009197; 20050020926; 20050068612; 20050104675; 20050147017; 20050167508; 20050199047; 20050274888; 20060032308; 20060032309; 20060033588; 20060158662; 20060158666; 20060196266; 20060233498; 20070016074; 20070024840; 20070034005; 20070115440; 20070119258; 20070142718; 20070194239; 20070287923; 20070289382; 20080007693; 20080190198; 20080190200; 20080191132; 20090036761; 20090064781; 20090174885; 20090229020; 20090289606; 20090301193; 20100000289; 20100024546; 20100024560; 20100078564; 20100137143; 20100145180; 20100155883; 20100194374; 20100213791; 20100253332; 20100267164; 20100301398; 20100308930; 20100313657; 20110006196; 20110028807; 20110040161; 20110138891; 20110167908; 20110170108; 20110194711; 20110194857; 20110227448; 20110248320; 20110275522; 20110281737; 20110281741; 20120006114; 20120009713; 20120013392; 20120032747; 20120068776; 20120086307; 20120112056; 20120168605; 20120172256; 20120187983; 20120192647; 20120194107; 20120227498; 20120261274; 20120265474; 20120304341; 20120325683; 20120326213; 20120326767; 20120327368; 20120329043; 20120329044; 20120329192; 20130001653; 20130004948; 20130004949; 20130009214; 20130017642; 20130025368; 20130064035; 20130071915; 20130119243; 20130139285; 20130180333; 20130201316; 20130210128; 20130210182; 20130217004; 20130231870; 20130247669; 20130271123; 20130302932; 20140000344; 20140028997; 20140062619; 20140093881; 20140104618; 20140113828; 20140144230; 20140147337; 20140159748; 20140159826; 20140176958; 20140185054; 20140194301; 20140194302; 20140194303; 20140224971; 20140230547; 20140235452; 20140235463; 20140251017; 20140265720; 20140287958; 20140301167; 20140324376; 20140331367; 20140360272; 20140372057; 20150029490; 20150043002; 20150065837; 20150085249; 20150091477; 20150143905; 20150166332; 20150168344; 20150171595; 20150177272; 20150293243; 20150304741; 20150308829; 20150377622; 20150377623; 20150377916; 20150377917; 20150377918; 20160003868; 20160006414; 20160033448; 20160035314; 20160054400; 20160061772; 20160062112; 20160069686; 20160072472; 20160079953; 20160087551; 20160139176; 20160187289; 20160223319; 20160298963; 20160329682; 20160341758; 20160341761; 20160341762; 20160341765; 20160344368; 20160374703; 20170003314; 20170003316; 20170025736; 20170059530; 20170067856; 20170068319; 20170074640; 20170078400; 20170126206; 20170146484; 20170153319; 20170155225; 20170164839; 20170176596; 20170184644; 20170185954; 20170194985; 20170199277; 20170201059; 20170205223; 20170219521; 20170219622; 20170258320; 20170271610; 20170272878; 20170272886; 20170276723; 20170277125; 20170277138; 20170277902; 20170278226; 20170278447; 20170278465; 20170278480; 20170278733; 20170278874; 20170278878; 20170278973; 20170280041; 20170280265; 20170281083; 20170285404; 20170285815; 20170285871; 20170286588; 20170287127; 20170287228; 20170287293; 20170287414; 20170287943; 20170288023; 20170288125; 20170288670; 20170289678; 20170289702; 20170290097; 20170293155; 20170293156; 20170293171; 20170294543; 20170295325; 20170295434; 20170297895; 20170297899; 20170299494; 20170299721; 20170300162; 20170301391; 20170301699; 20170308216; 20170309856; 20170310743; 20170316487; 20170316713; 20170317610; 20170318388; 20170318394; 20170319179; 20170320726; 20170323481; 20170323892; 20170323908; 20170325025; 20170325081; 20170328702; 20170328931; 20170329162; 20170329439; 20170331899; 20170332170; 20170334187; 20170336205; 20170336396; 20170336903; 20170337888; 20170338107; 20170338108; 20170338353; 20170338818; 20170340396; 20170343874; 20170344114; 20170347886; 20170348095; 20170352233; 20170352540; 20170352746; 20170354031; 20170355591; 20170355599; 20170356928; 20170357113; 20170357144; 20170357365; 20170359113; 20170359536; 20170359658; 20170359669; 20170362648; 20170363493; 20170363906; 20170364154; 20170365224; 20170365234; 20170365451; 20170365648; 20170366104; 20170366235; 20170366898; 20170367578; 20170370869; 20170372114; 20170372542; 20170372669; 20170373196; 20170374441; 20170374442; 20170374457; 20170374469; 20170374473; 20170374474; 20180000344; 20180002159; 20180002160; 20180002161; 20180002162; 20180002167; 20180002168; 20180004047; 20180004282; 20180004701; 20180004702; 20180005566; 20180005588; 20180005600; 20180005946; 20180006356; 20180007032; 20180007472; 20180007473; 20180007474; 20180009374; 20180011355; 20180011447; 20180011590; 20180012536; 20180012538; 20180012912; 20180013003; 20180014128; 20180017996; 20180018014; 20180018565; 20180018752; 20180018918; 20180018934; 20180019425; 20180020291; 20180021679; 20180024241; 20180024286; 20180024546; 20180024656; 20180024680; 20180025297; 20180025905; 20180025913; 20180025918; 20180026037; 20180026218; 20180027325; 20180027339; 20180029878; 20180031601; 20180031603; 20180031943; 20180032160; 20180032163; 20180033362; 20180033399; 20180033696; 20180033978; 20180034912; 20180035190; 20180035229; 20180038699; 20180039117; 20180039302; 20180039815; 20180040274; 20180040642; 20180040722; 20180041140; 20180042513; 20180044167; 20180046004; 20180046305; 20180047260; 20180047582; 20180047609; 20180048359; 20180048953; 20180050900; 20180052274; 20180052535; 20180052844; 20180052950; 20180052951; 20180053459; 20180055159; 20180055625; 20180058967; 20180059318; 20180059466; 20180059690; 20180061344; 20180061638; 20180061639; 20180063647; 20180067005; 20180067303; 20180067373; 20180067586; 20180069064; 20180069367; 20180070821; 20180072033; 20180074592; 20180075924; 20180076195; 20180076231; 20180076232; 20180076332; 20180076333; 20180076385; 20180076394; 20180076507; 20180076893; 20180077408; 20180077497; 20180077499; 20180079429; 20180081449; 20180081536; 20180082102; 20180082118; 20180083048; 20180083074; 20180084245; 20180084365; 20180085593; 20180085859; 20180086628; 20180087984; 20180088068; 20180088236; 20180088776; 20180090602; 20180090616; 20180090621; 20180091906; 20180092313; 20180093117; 20180095127; 20180095336; 20180095502; 20180095504; 20180096177; 20180096735; 20180096971; 20180096979; 20180097040; 20180097275; 20180097516; 20180097622; 20180097983; 20180098001; 20180098139; 20180098143; 20180099867; 20180099868; 20180100721; 20180101359; 20180101388; 20180101422; 20180101715; 20180101965; 20180102086; 20180102420; 20180102442; 20180102586; 20180102667; 20180102981; 20180103029; 20180103132; 20180103320; 20180103323; 20180103324; 20180103325; 20180104407; 20180105270; 20180106759; 20180107221; 20180107280; 20180107303; 20180107333; 20180107353; 20180107382; 20180107849; 20180107908; 20180108002; 20180108172; 20180108227; 20180108440; 20180108760; 20180109061; 20180109180; 20180109267; 20180109676; 20180109710; 20180109724; 20180109751; 20180109752; 20180109835; 20180109869; 20180109875; 20180109892; 20180109947; 20180110148; 20180110466; 20180111824; 20180112837; 20180112887; 20180113138; 20180113304; 20180113305; 20180113501; 20180113512; 20180113566; 20180113607; 20180114047; 20180114386; 20180114942; 20180115116; 20180115579; 20180115755; 20180115756; 20180115811; 20180115836; 20180115837; 20180115838; 20180115864; 20180115867; 20180116514; 20180116535; 20180116561; 20180116728; 20180116904; 20180117341; 20180117436; 20180118560; 20180120172; 20180120264; 20180120265; 20180120433; 20180120436; 20180120902; 20180120930; 20180120948; 20180121067; 20180121671; 20180121703; 20180121738; 20180121796; 20180122356; 20180122506; 20180122831; 20180123224; 20180123379; 20180123402; 20180123412; 20180124181; 20180124225; 20180124230; 20180124495; 20180124514; 20180124521; 20180124564; 20180124601; 20180124846; 20180125363; 20180125366; 20180125404; 20180125584; 20180126075; 20180126273; 20180127265; 20180127266; 20180128783; 20180128851; 20180128896; 20180129112; 20180129170; 20180129290; 20180129409; 20180129459; 20180129511; 20180129831; 20180129849; 20180130318; 20180130320; 20180130434; 20180130441; 20180130483; 20180130484; 20180130539; 20180130861; 20180130940; 20180130967; 20180131091; 20180131201; 20180131478; 20180131543; 20180131664; 20180131797; 20180131804; 20180131858; 20180131869; 20180131873; 20180132023; 20180132024; 20180132031; 20180132043; 20180132048; 20180132116; 20180132171; 20180132192; 20180132815; 20180133431; 20180133504; 20180133507; 20180133583; 20180133801; 20180134385; 20180134546; 20180136321; 20180136363; 20180136712; 20180136715; 20180136801; 20180136819; 20180136899; 20180137467; 20180137488; 20180137498; 20180138102; 20180138155; 20180138201; 20180138283; 20180138391; 20180138416; 20180138882; 20180139389; 20180139398; 20180139431; 20180139534; 20180139536; 20180139543; 20180139544; 20180139545; and 20180139862; each of which is expressly incorporated herein by reference in its entirety.

Microelectromechanical electrostatic actuators of various types are known. See: U.S. Pat. Nos. 6,128,122; 6,164,134; 6,201,629; 6,273,544; 6,309,048; 6,312,114; 6,353,492; 6,360,035; 6,378,989; 6,408,878; 6,424,466; 6,433,911; 6,439,689; 6,439,699; 6,443,558; 6,450,628; 6,474,781; 6,481,835; 6,491,362; 6,508,546; 6,517,197; 6,531,668; 6,538,799; 6,547,371; 6,554,410; 6,572,220; 6,575,566; 6,588,882; 6,592,207; 6,594,057; 6,598,964; 6,623,108; 6,634,735; 6,641,273; 6,644,793; 6,652,082; 6,666,548; 6,698,867; 6,733,116; 6,742,873; 6,746,108; 6,786,573; 6,793,328; 6,793,753; 6,798,729; 6,799,835; 6,805,435; 6,805,454; 6,808,253; 6,824,257; 6,827,428; 6,827,429; 6,832,828; 6,848,181; 6,851,796; 6,860,590; 6,863,378; 6,863,384; 6,866,369; 6,880,235; 6,880,922; 6,883,904; 6,883,906; 6,886,915; 6,890,059; 6,891,240; 6,899,137; 6,899,416; 6,902,255; 6,905,195; 6,905,620; 6,913,347; 6,916,087; 6,916,091; 6,918,655; 6,921,150; 6,922,118; 6,923,526; 6,929,030; 6,929,350; 6,938,989; 6,938,991; 6,938,994; 6,949,756; 6,955,428; 6,974,206; 6,988,785; 6,988,789; 6,988,790; 6,991,318; 6,994,424; 6,994,426; 6,994,430; 6,998,278; 7,001,007; 7,004,563; 7,004,577; 7,006,720; 7,014,296; 7,014,298; 7,014,785; 7,025,324; 7,028,474; 7,032,992; 7,032,997; 7,034,854; 7,040,338; 7,048,868; 7,052,114; 7,052,120; 7,064,883; 7,066,579; 7,070,256; 7,070,258; 7,073,881; 7,080,893; 7,080,895; 7,083,262; 7,086,717; 7,101,020; 7,111,924; 7,132,056; 7,134,740; 7,144,519; 7,144,616; 7,147,304; 7,147,307; 7,152,944; 7,152,961; 7,152,967; 7,155,823; 7,159,968; 7,160,475; 7,168,167; 7,169,314; 7,175,775; 7,178,899; 7,182,431; 7,182,437; 7,183,618; 7,184,193; 7,188,935; 7,188,938; 7,189,334; 7,198,346; 7,207,656; 7,210,764; 7,216,671; 7,216,956; 7,219,427; 7,219,982; 7,226,147; 7,227,687; 7,229,154; 7,233,101; 7,234,795; 7,249,830; 7,250,128; 7,258,421; 7,258,774; 7,264,333; 7,273,270; 7,278,713; 7,282,834; 7,284,836; 7,290,859; 7,293,855; 7,322,680; 7,328,975; 7,331,101; 7,331,659; 7,334,874; 7,338,147; 7,347,535; 7,347,697; 7,350,901; 7,350,906; 7,354,787; 7,359,106; 7,360,871; 7,370,942; 7,375,872; 7,380,339; 7,380,906; 7,380,913; 7,384,131; 7,387,365; 7,387,368; 7,393,083; 7,396,108; 7,399,068; 7,401,884; 7,401,895; 7,401,900; 7,401,906; 7,410,243; 7,410,250; 7,413,293; 7,416,275; 7,419,244; 7,419,247; 7,419,250; 7,431,427; 7,434,919; 7,441,867; 7,442,317; 7,447,547; 7,448,728; 7,457,021; 7,467,850; 7,468,997; 7,472,984; 7,475,965; 7,494,555; 7,506,966; 7,517,055; 7,524,029; 7,524,032; 7,527,357; 7,528,691; 7,537,314; 7,537,325; 7,549,726; 7,553,001; 7,556,351; 7,556,352; 7,556,353; 7,556,358; 7,556,361; 7,562,962; 7,562,963; 7,569,926; 7,578,569; 7,578,582; 7,585,047; 7,585,066; 7,588,327; 7,591,539; 7,591,541; 7,597,435; 7,601,270; 7,611,220; 7,615,744; 7,616,367; 7,625,061; 7,625,067; 7,625,068; 7,628,468; 7,637,582; 7,654,628; 7,654,642; 7,658,473; 7,661,793; 7,661,796; 7,661,797; 7,669,950; 7,669,951; 7,669,964; 7,669,971; 7,673,976; 7,677,685; 7,677,686; 7,699,440; 7,703,890; 7,708,372; 7,708,381; 7,717,542; 7,731,334; 7,731,336; 7,731,341; 7,735,963; 7,735,968; 7,740,337; 7,746,538; 7,748,827; 7,753,469; 7,753,487; 7,753,491; 7,753,504; 7,754,010; 7,758,160; 7,758,162; 7,758,166; 7,758,171; 7,762,638; 7,766,055; 7,771,025; 7,771,032; 7,775,634; 7,780,264; 7,784,905; 7,784,910; 7,794,050; 7,815,290; 7,815,291; 7,835,055; 7,864,006; 7,874,644; 7,891,773; 7,893,798; 7,896,468; 7,896,473; 7,901,023; 7,905,574; 7,905,588; 7,914,115; 7,918,540; 7,918,541; 7,931,351; 7,934,797; 7,934,799; 7,934,808; 7,938,524; 7,939,994; 7,946,671; 7,950,771; 7,950,773; 7,950,774; 7,960,208; 7,967,422; 7,971,967; 7,971,972; 7,971,975; 7,973,278; 7,976,131; 7,987,784; 7,992,968; 8,002,933; 8,011,757; 8,021,614; 8,025,355; 8,047,633; 8,057,014; 8,061,795; 8,066,355; 8,079,669; 8,079,688; 8,087,740; 8,087,757; 8,104,497; 8,104,515; 8,104,878; 8,110,813; 8,124,218; 8,167,406; 8,220,487; 8,226,199; 8,226,217; 8,231,207; 8,251,495; 8,264,307; 8,282,181; 8,282,202; 8,288,211; 8,323,982; 8,336,990; 8,376,513; 8,382,258; 8,382,259; 8,393,714; 8,398,210; 8,398,221; 8,398,222; 8,419,176; 8,440,093; 8,444,260; 8,455,570; 8,459,787; 8,465,129; 8,465,142; 8,468,939; 8,469,496; 8,480,224; 8,485,654; 8,506,039; 8,517,516; 8,523,327; 8,523,328; 8,529,021; 8,530,854; 8,534,818; 8,550,119; 8,562,120; 8,585,189; 8,585,971; 8,602,531; 8,602,535; 8,604,411; 8,629,393; 8,632,162; 8,633,955; 8,641,175; 8,646,882; 8,646,883; 8,651,632; 8,651,633; 8,652,409; 8,656,958; 8,657,419; 8,659,631; 8,668,312; 8,668,313; 8,684,483; 8,695,640; 8,696,094; 8,714,676; 8,717,395; 8,736,081; 8,770,722; 8,783,804; 8,784,549; 8,791,971; 8,802,568; 8,806,751; 8,845,914; 8,846,183; 8,847,148; 8,916,395; 8,929,584; 8,932,677; 8,936,353; 8,936,354; 8,939,551; 8,991,986; 8,992,858; 9,010,909; 9,017,537; 9,103,761; 9,151,949; 9,162,878; 9,174,222; 9,174,438; 9,234,797; 9,508,823; 9,653,254; 9,696,375; 9,799,488; 9,897,530; 9,953,787; 9,956,562; 20010021058; 20010022682; 20010029983; 20010033796; 20010045525; 20010054778; 20020024569; 20020029814; 20020033863; 20020036674; 20020097300; 20020101474; 20020122102; 20020127736; 20020130931; 20020144738; 20020171716; 20030016275; 20030019833; 20030020784; 20030020786; 20030025758; 20030025761; 20030042117; 20030063166; 20030081082; 20030103106; 20030132824; 20030132985; 20030132995; 20030137567; 20030142175; 20030146957; 20030174190; 20030202055; 20030202735; 20030202738; 20040001263; 20040031150; 20040032440; 20040051759; 20040056923; 20040056924; 20040075715; 20040075718; 20040079724; 20040080556; 20040085159; 20040092121; 20040094506; 20040095434; 20040095441; 20040099636; 20040100529; 20040113983; 20040118808; 20040119784; 20040160495; 20040169697; 20040169701; 20040207687; 20040207689; 20040207690; 20040207691; 20040218016; 20040218022; 20040246305; 20040246308; 20040246311; 20040257400; 20040263551; 20040263577; 20050016951; 20050018015; 20050018016; 20050018017; 20050024434; 20050024435; 20050024436; 20050024437; 20050024443; 20050030338; 20050030339; 20050030342; 20050030343; 20050035983; 20050036002; 20050037532; 20050039453; 20050041052; 20050041055; 20050041063; 20050046663; 20050046673; 20050052497; 20050052514; 20050057628; 20050083377; 20050093933; 20050093934; 20050097742; 20050099465; 20050099466; 20050104922; 20050109730; 20050110832; 20050112882; 20050116990; 20050128247; 20050128249; 20050131490; 20050134648; 20050134649; 20050140726; 20050140728; 20050144781; 20050144782; 20050146559; 20050146562; 20050146563; 20050146566; 20050157042; 20050157081; 20050157082; 20050166980; 20050167769; 20050168532; 20050168533; 20050174375; 20050174394; 20050185021; 20050189316; 20050189317; 20050200659; 20050206684; 20050215089; 20050225601; 20050225602; 20050225604; 20050226742; 20050231560; 20050237743; 20050242058; 20050243134; 20050248620; 20050253897; 20050264607; 20050264612; 20050269901; 20050270335; 20050270338; 20050275690; 20050275691; 20050279090; 20050285901; 20060007266; 20060007514; 20060017772; 20060018005; 20060033785; 20060034006; 20060054228; 20060061628; 20060072187; 20060077235; 20060092220; 20060093753; 20060098047; 20060109310; 20060109313; 20060119661; 20060152551; 20060197810; 20060202933; 20060227156; 20060227167; 20060227168; 20060238571; 20060250448; 20060268048; 20060268064; 20060274119; 20060274121; 20070002009; 20070008386; 20070008390; 20070030315; 20070030321; 20070046759; 20070048887; 20070048898; 20070052766; 20070059494; 20070064034; 20070064037; 20070064066; 20070064067; 20070070133; 20070070161; 20070080695; 20070081031; 20070109345; 20070115316; 20070120891; 20070146432; 20070153058; 20070176967; 20070176968; 20070176971; 20070182784; 20070182785; 20070183643; 20070188554; 20070188556; 20070188557; 20070188570; 20070211102; 20070211112; 20070222807; 20070222819; 20070222821; 20070222826; 20070236313; 20070257966; 20070257971; 20070268327; 20070268343; 20070291070; 20070291091; 20070296765; 20080012913; 20080012923; 20080024556; 20080030544; 20080036821; 20080050283; 20080079760; 20080094432; 20080111853; 20080111863; 20080117258; 20080129800; 20080129809; 20080141884; 20080165226; 20080173365; 20080180778; 20080192096; 20080204514; 20080204518; 20080204519; 20080210319; 20080210320; 20080210321; 20080210322; 20080211876; 20080211877; 20080211879; 20080220216; 20080220535; 20080231669; 20080236669; 20080246817; 20080252691; 20080266341; 20080266356; 20080266361; 20080273059; 20080277005; 20080277007; 20080277258; 20080278268; 20080278559; 20080289710; 20080303866; 20080303871; 20080309693; 20080309694; 20080309695; 20080309696; 20080309697; 20080309699; 20080309720; 20080309721; 20080309722; 20080316240; 20080316241; 20080316242; 20080316262; 20080316271; 20080316276; 20080318349; 20090002470; 20090027448; 20090027459; 20090085975; 20090091601; 20090091603; 20090121156; 20090122116; 20090124029; 20090128604; 20090151422; 20090153619; 20090153936; 20090160910; 20090174014; 20090185007; 20090189953; 20090195598; 20090195614; 20090201339; 20090213186; 20090213191; 20090237433; 20090237450; 20090237456; 20090237461; 20090244193; 20090244194; 20090256890; 20090261244; 20090278897; 20090289979; 20090295861; 20090303290; 20090303297; 20090303303; 20090309909; 20090322812; 20100003772; 20100026765; 20100039478; 20100050415; 20100053268; 20100053274; 20100053275; 20100053276; 20100073441; 20100110129; 20100110130; 20100118071; 20100149268; 20100149274; 20100175767; 20100187105; 20100200782; 20100201750; 20100208000; 20100231645; 20100242765; 20100253745; 20100265298; 20100276588; 20100276606; 20100277549; 20100295887; 20100302292; 20110024923; 20110025350; 20110025780; 20110037796; 20110037797; 20110037809; 20110090288; 20110109675; 20110109677; 20110109705; 20110155548; 20110164081; 20110204018; 20110205306; 20110205319; 20110258851; 20110261123; 20110261124; 20110261125; 20110261126; 20110271857; 20120026251; 20120026252; 20120026253; 20120026259; 20120026260; 20120026261; 20120038695; 20120045615; 20120056952; 20120091374; 20120105535; 20120105548; 20120105549; 20120105550; 20120105553; 20120268525; 20120268527; 20120268528; 20120268529; 20120268530; 20120268531; 20120299998; 20120299999; 20120300000; 20120300001; 20120307211; 20120319303; 20120328834; 20130059396; 20130068131; 20130070031; 20130072614; 20130199730; 20130235101; 20130235102; 20130249982; 20130249983; 20130249984; 20130249985; 20130252234; 20130257991; 20130257992; 20130257994; 20130257996; 20130257997; 20130258002; 20130278677; 20130278689; 20130280831; 20130286108; 20130286109; 20130302785; 20130328976; 20130328977; 20130330475; 20130342597; 20140009523; 20140015878; 20140015879; 20140015880; 20140015893; 20140015901; 20140021343; 20140084390; 20140126762; 20140212917; 20140220621; 20140262972; 20140273408; 20140308770; 20140322489; 20140363678; 20150043002; 20150183633; 20150213996; 20150266726; 20150276089; 20150294838; 20160091479; 20160103174; 20160172197; 20160173001; 20160202286; 20160243827; 20160268084; 20160324564; 20170001195; 20170146364; 20170303383; 20180075994; and 20180079640; each of which is expressly incorporated herein by reference in its entirety.

It is an object to provide a sensor, comprising at least two electrodes within an electrical field; and an elongated displaceable element configured to be charged, disposed proximate to the at least two electrodes within the electrical field, and having an aspect ratio of at least 10, the element being configured to interact with each of the at least two electrodes to produce a composite force within the element that is at least 95% tensile along an elongated axis, such that the element when displaced by a condition, induces a charge redistribution on the at least two electrodes corresponding to a magnitude of the condition substantially without altering a responsivity of the charge redistribution to the condition or pull-in instability.

It is also an object to provide a sensor, comprising: an element configured to be charged, disposed proximate to at least two electrodes within an electrical field, the element interacting with each of the at least two electrodes to produce a composite force within the element that is at least 95% tensile, such that the element when displaced from the nominal position by a condition, induces a charge redistribution on the at least two electrodes corresponding to a magnitude of the condition. The at least two electrically isolated and separated electrodes may comprise a pair of fixed conductors, separated by a linear gap, each of the pair of fixed conductors may be maintained at a respective electric potential, and sensing an electrical field in a space above the pair of fixed conductors based on charge redistribution. The axis preferably has a vector component directed across the linear gap, wherein the net force on the charged element is insensitive to a state of displacement of the charged element in response to the sensed condition.

It is also an object to provide a method for sensing a capacitive difference, comprising: providing a charged element in an electric field, having a movement along an axis in response to a sensed condition; proving at least two electrically isolated and separated conductors, each interacting with the electric field, and having a respective electrode for electrically sensing a perturbation of the electric field, the at least two electrically isolated and separated conductors producing a net force on the charged element normal to the axis; and sensing a perturbation of the electric field caused by movement of the charged element along the axis in response to the condition, wherein over a range of the movement of the charged element, a position of the charged element in the electric field does not substantially alter a responsivity of the displaceable element to the condition or cause pull-in instability.

The at least two electrically isolated and separated conductors may comprise a pair of fixed conductors, separated by a linear gap, each of the pair of fixed conductors being maintained at a respective electric potential, to sense an electrical field in a space above the pair of fixed conductors based on charge redistribution, and the axis may have a vector component directed across the gap, wherein the net force on the charged element is insensitive to a state of displacement of the charged element in response to the sensed condition.

The charged element may be responsive to acoustic vibrations, and the sensed perturbation quantitatively represents the acoustic vibrations.

The charged element may have an elongated axis, being suspended from one end, having a restoring force which tends to return the charged element to a nominal position, and in the nominal position a free end of the charged element being proximate to the at least two electrically isolated and separated electrodes. A vector of the net force between the charged element and the at least two electrically isolated and separated electrodes may deviate from the elongated axis by less than 5 degrees, e.g., 4 degrees, 3 degrees, 2 degrees, 1 degree, etc.

It is a further object to provide a capacitive sensor, comprising at least two conductors, isolated from each other by at least one spatial gap, each respective conductor interacting with an electrostatic field occupying a region proximate to the at least two conductors and the at least one spatial gap, being electrically responsive to a perturbation of the electrostatic field; and a displaceable element configured to move along an axis of displacement having a directional component crossing the spatial gap selectively responsive to a sensed condition, and perturbing the electrostatic field corresponding to the movement, wherein over a range of the movement of the displaceable element, the electrostatic field does not substantially alter a responsivity of the displaceable element to the sensed condition or cause pull-in instability.

The at least two conductors may comprise a pair of fixed conductors, separated by a linear spatial gap, each of the pair of fixed conductors being maintained at a respective electric potential, to generate the electrostatic field in a space above the pair of fixed conductors having a major field vector component directed across the linear spatial gap dependent on a difference between the respective electric potentials of the pair of fixed conductors, and the displaceable element may comprise a charged element configured with the axis of displacement having a vector component directed across the linear spatial gap, such that a force imposed on the displaceable element due to the electrostatic field is insensitive to a state of displacement of the displaceable element in response to the sensed condition.

The displaceable element is unsupported on at least one edge.

The displaceable element comprises a metallic or metallized polymer diaphragm having a thickness of less than about 10 μm; a fiber; a mesh; at least one of a carbon nanotube and a graphene sheet; and/or an electret, a thin metal sheet, polysilicon or any doped semiconductor.

The displaceable element may be configured to displace along two different sensing axes, and the at least two conductors comprises at least three conductors.

The displaceable element may comprise a diaphragm, and the at least two fixed conductors be together configured such that a change in an electric potential difference between the diaphragm and either of the at least two fixed conductors does not substantially displace or alter an effective stiffness of the diaphragm with respect to the axis of displacement.

The capacitive sensor may further comprise a respective transimpedance amplifier configured to produce an output signal from each respective conductor.

The displaceable element may comprise a micromachined silicon diaphragm having opposite sides which are sufficiently isolated to maintain a pressure difference across the diaphragm, further comprising a housing configured to selectively define at least one path for a fluid medium from a respective environmental port to a respective side of the micromachined silicon diaphragm, to selectively alter the pressure on the respective side of the micromachined silicon diaphragm.

The deflectable element may have a movement dynamically responsive to changes in inertial state. The deflectable element may have a movement dynamically responsive to aerodynamic influences. The deflectable element may have a movement dynamically responsive to a chemical or biochemical process.

A potential between the displaceable element and at least one of the conductors may be at least 1 V, e.g., 3V, 5V, 10V, 15V, 20V, 30V, 50V, 100V, 200V, 300V, 400V, or 500V. The electric field between the displaceable element and at least one of the conductors is at least 0.1 V/mm, e.g., 0.5V/mm, 1V/mm, 2V/mm, 3V/mm, 4V/mm, 5V/mm, 10V/mm, 25V/mm, 50V/mm, 75V/mm, 100V/mm, 200V/mm, 300V/mm, 400V/mm, 500V/mm, 750V/mm, 1000V/mm, 1500V/mm, 2000V/mm, 2500V/mm, etc. In some cases, the potential may be established at the dielectric strength of the isolating medium. For example, air has a dielectric strength of about 3000V/mm.

It is therefore an object to provide a capacitive sensor, comprising: a pair of coplanar surfaces, separated by a gap; a diaphragm, disposed in a plane perpendicular to the coplanar surfaces, and configured to move along an axis perpendicular to the gap and parallel to the coplanar surfaces, the diaphragm and the pair of coplanar surfaces being together configured such that a voltage difference between the conductive diaphragm and either of the pair of coplanar conductive surfaces does not substantially deflect or alter an effective stiffness of the diaphragm; and a set of electrodes, in electrical communication with each of the pair of coplanar surfaces and the diaphragm, configured to determine a differential charge induced between the pair of coplanar surfaces by a potential of the diaphragm.

It is also an object to provide a method of sensing a vibration or sound, comprising: providing a pair of coplanar surfaces, separated by a gap, and a diaphragm, disposed in a plane perpendicular to the coplanar surfaces, configured to flex along an axis perpendicular to the gap and parallel to the coplanar surfaces; inducing a voltage potential on the diaphragm with respect to the pair of coplanar surfaces; and sensing a change in induced charge on the pair of coplanar surfaces resulting from flexion of the diaphragm along the perpendicular axis, wherein the diaphragm and the pair of coplanar surfaces are together configured such that the voltage potential does not substantially deflect or alter an effective stiffness of the diaphragm.

The sensor may further comprise a transimpedance amplifier configured to amplify the differential charge. A potential at each of the coplanar surfaces may be maintained at ground potential by a respective transimpedance amplifier while a change in charge is induced on the respective coplanar surfaces by a movement of the diaphragm.

The diaphragm may comprise a metallized polymer membrane or micromachined silicon, for example, having a thickness of, e.g., <10 μm, <7.5 μm, <5 μm, <3 μm, <2 μm, <1 μm, for example.

The diaphragm is preferably configured to oscillate, e.g., in response to acoustic vibrations, e.g., sounds produced by human speech, or electric field variations, though it may act as an electrometer, accelerometer, shock sensor, flow sensor, or other type of electrical or mechanical sensor.

The sensor may further comprise a housing configured to selectively direct acoustic vibrations from an environmental port to one side of the diaphragm, or from each of a pair of environmental ports to respective sides of the diaphragm, or provide a defined path for a fluid medium from an environmental port to one side of the deflectable element.

The diaphragm may have a movement which approximates an air movement within a sound field.

The diaphragm has a lowest resonant frequency of movement, and may be configured to have a velocity of movement in response to a movement of air within a sound field having a frequency above the lowest resonant frequency approximately in-phase with an acoustic velocity of the acoustic waves. The lowest resonant frequency may be <250 Hz, <200 Hz, <150 Hz, <100 Hz, <80 Hz, <50 Hz, <35 Hz, <24 Hz, <20 Hz, <15 Hz, or <10 Hz, for example.

A potential between the diaphragm and at least one of the coplanar surfaces may be >400 V, >200 V, >100V, >50V, >24V, >12V, >10V, >6V, or >5V, for example.

It is also an object to provide a capacitive sensor, comprising at least two fixed conductive surfaces, separated by at least one non-conductive gap, each having an associated electrostatic field, and together causing a composite force vector; and a deflectable element configured to move along an axis perpendicular to the composite force vector, having an amplitude of movement corresponding to a sensed condition, the element being configured to have an electrostatic interaction with the associated electrostatic field of each of the pair of fixed conductive surfaces, wherein over a range of the movement of the element along the axis, the composite force vector does not substantially alter a deflection of the deflectable element. The capacitive sensor may be a microphone, and the sensed condition comprise acoustic waves.

The deflectable element may comprise a diaphragm, e.g., a cantilever supported diaphragm, a diaphragm or beam supported on opposed edges (and free to flex between the supports), a perforated diaphragm, a solid diaphragm, or a metallized polymer diaphragm. The deflectable element may comprise a fiber, a fiber mesh, a fiber mat, or a metallized electrospun fiber. The deflectable element may have a solid edge, e.g., an intrinsic part of a mechanical diaphragm, or a fiber mesh having a solid border element. The deflectable element may comprise a carbon nanotube, graphene, silicon, micromachined silicon or other material, and/or silicon nitride. The deflectable element may be metallized, a doped semiconductor, or an electret. The sensor may be manufactured using an additive manufacturing process, a subtractive manufacturing process, or aspects of each. For example, semiconductor fabrication typically employs both deposition and etching. The manufacturing process may be customized to produce a single sensor, or an array of sensors.

A moving electrode may be provided that represents a beam or plate supported on opposite ends with two free edges. These two edges may be adjacent to pairs of fixed electrodes, similar to those shown in FIG. 2. This configuration looks a lot like a ribbon microphone, allows capacitive transduction rather than electrodynamic, as in all ribbon microphones. Using capacitive transduction enables miniaturization, which is extremely difficult with electrodynamic transduction.

The deflectable element may be configured to oscillate in response to acoustic vibrations.

The deflectable element may be configured to deflect in response to vibrations or acoustic waves along a single axis, along two axes, or have a greater number of degrees of freedom (e.g., rotational, internal vibrations and harmonics, flexion, etc.).

The at least two fixed conductive surfaces may be coplanar or reside in different planes. The at least two fixed conductive surfaces may comprise at least three conductive surfaces.

The deflectable element may comprise a diaphragm, and the at least two fixed conductive surfaces be together configured such that a voltage difference between the diaphragm and either of the at least two fixed conductive surfaces does not substantially deflect or alter an effective stiffness of the diaphragm.

The capacitive sensor may further comprise a set of electrodes, in electrical communication with each of the at least two pair of conductive surfaces, configured to determine a charge redistribution induced between the movement of the deflectable element.

A respective transimpedance amplifier may be provided, configured to produce an output signal from each respective conductive surface.

The capacitive sensor may have a housing configured to selectively direct acoustic vibrations from an environmental port to one side of the deflectable element, or to selectively direct acoustic vibrations from each of a pair of environmental ports to respective sides of the deflectable element. The housing may be configured to selectively provide a set of defined paths from a fluid medium from each of a pair of environmental ports to respective sides of the deflectable element.

The deflectable element may have a movement which approximates an air movement within a sound field surrounding the deflectable element. The deflectable element may have a movement which corresponds to an inertial state of the deflectable element, i.e., acceleration, angular rotation, etc.

The deflectable element may comprise a diaphragm having a thickness of less than about 10 μm, 7.5 μm, 5 μm, 3 μm, or 1 μm. The deflectable element may comprise a fiber having a diameter of about 1 μm, less than 800 nm, 750 nm, 700 nm, 600 nm, 550 nm, 500 nm, 400 nm, 300 nm, 250 nm, 225 nm, 200 nm, 175 nm. 150 nm, 125 nm, 100 nm, 80 nm, 75 nm, 60 nm or 50 nm. The diaphragm or fiber may be metallized, for example with a coating of gold of <100 nm, 90 nm, 80 nm, 75 nm, 70 nm, 60 nm, 50 nm, 40 nm, 30 nm, 25 nm, 20 nm, 15 nm, or 10 nm.

The deflectable element has a lowest resonant frequency of movement, e.g., less than 250 Hz, 200 Hz, 175 Hz, 150 Hz, 125 Hz, 100 Hz, 80 Hz, 75 Hz, 70 Hz, 65 Hz, 60 Hz, 55 Hz, 50 Hz, 45 Hz, 40 Hz, 35 Hz, 30 Hz, 25 Hz, 20 Hz, 15 Hz, or 10 Hz. The deflectable element may be configured to move in response to changes in air pressure corresponding to acoustic waves within a sound field having a frequency above its lowest resonant frequency in-phase with an acoustic velocity of the acoustic waves.

A potential between the deflectable element and at least one of the conductive surfaces may be at least 400 V, 300 V, 240 V, 200 V, 150 V, 120 V, 100 V, 75 V, 48 V, 24 V, 12 V, 10 V, 6 V, 5 V, 3.3 V, 3 V, 2.5 V, 2 V, 1.5 V, 1 V, or 0.5 V.

The deflectable element may have a lowest resonant frequency of movement less than 250 Hz, and is configured to have a velocity which has a phase lag of less than 90 degrees of a movement of air in response to acoustic waves within a sound field having a frequency above the lowest resonant frequency. The deflectable element may have a lowest resonant frequency of movement less than 150 Hz, and is configured to have a velocity which has a phase lag of less than 90 degrees of a movement of air in response to acoustic waves within a sound field having a frequency above the lowest resonant frequency. The deflectable element may have a lowest resonant frequency of movement less than 80 Hz, and is configured to have a velocity which has a phase lag of less than 90 degrees of a movement of air in response to acoustic waves within a sound field having a frequency above the lowest resonant frequency. The deflectable element may have a lowest resonant frequency of movement less than 50 Hz, and is configured to have a velocity which has a phase lag of less than 90 degrees of a movement of air in response to acoustic waves within a sound field having a frequency above the lowest resonant frequency. The deflectable element may have a lowest resonant frequency of movement less than 25 Hz, and is configured to have a velocity which has a phase lag of less than 90 degrees of a movement of air in response to acoustic waves within a sound field having a frequency above the lowest resonant frequency. The deflectable element may have a lowest resonant frequency, and move with a phase lag of less than 90 degrees in response to pressure changes in air having a frequency above the lowest resonant frequency.

A potential at each of the conductive surfaces may be maintained at ground potential by a respective transimpedance amplifier while a change in charge is induced on the respective conductive surfaces by a movement of the deflectable element.

It is also an object to provide a method of sensing a vibration, comprising: providing at least two separated conductive surfaces, and a deflectable element, having an axis of deflection perpendicular to a force on the deflectable element generated by the at least two separated conductive surfaces; inducing a voltage potential on the deflectable element with respect to the at least two conductive surfaces; and sensing a change in induced charge on the at least two conductive surfaces resulting from deflection of the deflectable element along the axis of deflection, wherein the force on the deflectable element generated by the at least two separated conductive surfaces does not substantially alter a deflection of the deflectable element. The change in induced charge may be sensed by at least one transimpedance amplifier. The deflectable element may have a movement in response to acoustic waves in air at standard temperature and pressure, and 20% relative humidity, which approximates an air movement within a sound field surrounding the deflectable element.

The deflectable element may have a lowest resonant frequency, and moves with a phase lag of less than 90 degrees in response to an acoustic wave in air having a frequency above the lowest resonant frequency. The lowest resonant frequency is, for example, 250 Hz. The movement of the deflectable element may correspond to an external force, viscous drag, pressure differential, etc. The movement of the deflectable element may correspond to an external force, e.g., a change in stress or strain, expansion, contraction, swelling, heating, cooling, etc. of the deflectable element.

A potential at each of the conductive surfaces may be maintained at ground potential by a respective transimpedance amplifier while the deflection causes a movement of the deflectable element to induce the change in charge on the respective conductive surfaces.

It is a further object to provide a capacitive sensing method, comprising: providing a sensor comprising at least two electrically isolated electrodes having an associated electrical field, and a charged element within the associated electrical field, having an axis of movement in response to a sensed condition which is orthogonal to an electrostatic force between the charged element and the at least two electrically isolated electrodes, and being mechanically unresponsive to a magnitude of the electrostatic force between the charged element and the at least two electrically isolated electrodes; inducing a movement of the charged element with respect to the at least two electrically isolated electrodes along the axis of movement; sensing an induced charge on each of the at least two electrically isolated electrodes as a result of the movement of the charged element; and generating a signal corresponding to the movement. The sensed condition may be sound.

The charged element may be suspended from one end and have an elongated axis and has a restoring force which tends to return the charged element to a nominal position, and in the nominal position a free end of the charged element is proximate to the at least two electrically isolated electrodes, and the electrostatic force between the charged element and the at least two electrically isolated electrodes is parallel to the elongated axis.

The charged element may have an elongated axis and be supported by an elastic cantilever, the elongated axis being parallel to the electrostatic force and directed at a gap between the at least two electrically isolated electrodes.

Each of the at least two electrically isolated electrodes may exert a force component on the charged element along the axis of movement, wherein a superposition of the force components exerted on the charged element along the axis of movement cancels a net force along the axis of movement.

The charged element may comprise a filament, having a diameter less than about 1 micron. The charged element may comprise a filament or conductive filament having a diameter less than about 550 nm. The movement in air may be in response to an acoustic vibration at frequencies above 250 Hz dominated by viscous drag.

The charged element may comprise a conductive perforated plate having a cantilever support which supports movement of the conductive perforated plate only along the axis of movement. The charged element may have a movement in air in response to an acoustic vibration at frequencies above 100 Hz dominated by viscous drag.

The charged element may have an elongated profile and an elongated axis, the elongated axis having an angle with respect to a vector of the electrostatic force of less than about 3 degrees, less than 2 degrees, less than 1 degree, or less than 0.5 degree.

The charged element may have an elongated profile and an elongated axis perpendicular to the axis of movement, and a force component of the electrostatic force along the axis of movement is at least −18 dB, −20 dB, −24 dB, −28 dB, −30 dB, −33 dB. −36 dB, or −40 dB lower than a force component of the electrostatic force along elongated axis.

The charged element may have an elongated axis parallel to the electrostatic force, and have a tensile stiffness, and wherein the charged element is not subject to pull-in by the electrostatic force before the electrostatic force exceeds the tensile stiffness.

The at least two electrically isolated electrodes may be symmetric with respect to the charged element, and the signal be generated by providing a transimpedance amplifier for each respective electrode, and a movement of the charged element determined based on voltage differences in outputs of the respective transimpedance amplifiers.

It is another object to provide a directional microphone or sensor, comprising: at least two electrically isolated electrodes having an associated electrical field; a charged element within the associated electrical field, having an axis of movement about a fixed position, configured to move along the axis of movement, e.g., in response to sound, which is orthogonal to an electrostatic force between the charged element and the at least two electrically isolated electrodes; and an electronic circuit configured to produce an output dependent on the movement, e.g., in response to sound, and to produce a deflection force on the charged element, to thereby alter the axis of movement of the charged element. An input may receive a signal defining a desired axis of movement of the charged element.

It is also an object to provide a method of determining a propagation vector of a wave, e.g., a sound or vibration, comprising: providing at least two electrically isolated electrodes having an associated electrical field; and a charged element within the associated electrical field, having an axis of movement about a fixed position, configured to move about the axis of movement which is orthogonal to an electrostatic force between the charged element and the at least two electrically isolated electrodes; producing a first output dependent on the movement along the axis; receiving a signal for altering the associated electrical field and thereby deflecting the charged element, to thereby alter the axis of movement to a second axis of movement; producing a second output dependent on the movement along the second axis; and analyzing the first output and the second output to determine a vector propagation property of the vibration.

It is also an object to provide a sensor comprising a charged (or chargeable) element which is disposed within an electrical field having at least two electrodes, the charged or chargeable element interacting with each of the at least two electrodes to produce a composite force within the charged element that is tensile only does not have a deflection tendency from a nominal position of the charged element, such that the charged element when deflected from the nominal position induces a charge redistribution on the electrodes which can be sensed.

The deflection may be caused by various effects. For example, in a microphone embodiment, sound may act on the charged element to displace it in a movement pattern that corresponds to pressure variations or bulk flow patterns (e.g., viscous drag).

In an accelerometer embodiment, the charged element may be, or may have a movement corresponding to a proof mass or inertial mass.

In a shock sensor, the inertial mass has either a mechanical integration over time, or the output is electrically integrated over time, to determine the impulse magnitude.

Similarly, in a gyroscope (e.g., MEMS gyroscope), the charged element may be directly or indirectly responsive to a Coriolis force or gyroscopic reaction force.

The charged element may be a microcantilever beam, which, for example, can sense asymmetric bending effects. For example, if one side of a beam is coated with a chemically responsive material, and the other is not, or one side is selectively exposed to a chemical to which it is responsive, the deflection may be measured. Typically, the low frequency response (<1 Hz or 0.1 Hz) of the device may be low or subject to noise, and therefore the charged element may be induced to vibrate. In this case, the vibration will act as a frequency modulation of the offset position of the charged element.

The microcantilever may also be coated with a selective chemisorbent, which has the effect of changing the mass of the charged element based on an amount of exposure to a particular type of chemical species. In this case, it is often useful to sense the mass change of the charged element by vibrating the microcantilever, and sensing dynamic characteristics. For example, there the microcantilever has an elastic mount, the resonant frequency of movement of the charged element will depend on its mass. In non-resonant systems, the inertia of the charged element induced in response to a defined force will change with the mass of the charged element.

In some cases, the mount for the charged element has a relevant physical property that varies with a sensed condition. For example, the mount may be a thermally responsive material. Therefore, as the temperature of the mount changes, a mechanical property of the mounting of the charged element may be sensed. This may be a deflection, damping coefficient, spring force, or the like.

The charged element may also act as a sensor for fluid dynamical properties of the medium in which it is immersed. For example, instead of providing a fiber for which fluid drag is a dominating factor in the response to bulk flow, such as a submicron fiber, a larger fiber is provided which is in a transition region range. Therefore, the movement of the fiber in response to a standardized vibration within the medium will alter based on properties of the medium. If the medium is homogeneous and constant temperature and pressure, changes in mass and/or viscosity will be reflected in the response of the charged element.

In some cases, an array of sensors may be provided. For example, the array may sense spatial or volumetric differences in a condition, such as sound waves. Note that the charged element may be directional, and as a result, spatial and volumetric sensors may produce information about propagation vectors, scattering, and other influences. In other cases, the array of sensors may be configured or processed to null or cancel undesired signal components, and select or respond to desired signal components.

It is another object to provide a sensor, comprising an element configured to be charged disposed within an electrical field having at least two electrodes, the element interacting with each of the at least two electrodes to produce a composite force within the element that is tensile only, and without a deflection tendency from a nominal position, such that the element when deflected from the nominal position induces a charge redistribution on the at least two electrodes.

The element may have a movement or deflection responsive to an acceleration, Coriolis force, asymmetric bending force, a chemical interaction of a medium and a surface of the element, a biological interaction of a medium and a surface of the element, or a chemisorptive interaction of a medium and a surface of the element, for example. The sensor may further comprise a mechanical integrator, wherein the element has a movement responsive to a shock.

The composite force may be oscillating, and the element have a deflection responsive to at least the oscillating composite force.

The sensor may further comprise an electronic amplifier configured to produce a signal corresponding to the deflection of the element.

The sensor may further comprise an electronic device configured to determine analyze a time-response of the deflection of the element.

The time response may comprise a vibration frequency, a resonant frequency, or a phase delay.

The deflection of the element may be responsive to a temperature, pressure, an illumination, and/or a viscosity of a fluid surrounding the element, for example.

The sensor may further comprise an elastic mount for the element, which pivotally supports the element. The deflection of the element may be responsive to a change in physical properties of the elastic mount. The deflection of the element may be responsive to a chemical interaction of the elastic mount with a surrounding medium.

The element may have an associated catalyst, wherein a deflection of the element is responsive to an amount of substrate for the associated catalyst.

It is another object to provide a sensor array, comprising a plurality of elements arranged in a spatial array, the plurality of elements being configured to be electrically charged, each respective element of the spatial being disposed within an electrical field controlled by at least two respective electrodes, the respective element interacting with each of the at least two respective electrodes to produce a composite tensile force within the respective element, substantially without a deflection tendency from a nominal position due to the composite force, such that the respective element induces a charge redistribution on the at least two respective electrodes upon deflection. The spatial array may provide a three dimensional array of the plurality of elements. The sensor array may further comprise an external condition gradient surrounding the plurality of elements. The sensor array may further comprise a thermal control configured to create a thermal gradient in the plurality of elements. The sensor array may further comprise an optical system configured to project an image onto the spatial array. The respective elements may have a plurality of respective different selective chemical responses.

An array may also be provided in which the environment of the sensor is controlled to provide difference conditions, typically incrementally varying, over a range. For example, a linear array of sensors may be provided which are maintained at different temperatures. This may be as simple as providing a temperature gradient cause by a heat source at one end of the array. The array may then sense characteristics of the medium over the range of temperatures. Similarly, other gradients may be imposed, such as illumination or other electromagnetic radiation, magnetic field, distance from an axis of rotation, or the like.

As discussed above, chemisensors may be employed, and the array may have incrementally (or otherwise) varying properties of the sensors, environment of sensing, or the medium to be sensed.

The sensor may, for example, include a catalyst (inorganic, organic, enzyme, etc.) which selectively interacts with an analyte in the medium. This may produce various effects, but often heat (thermal energy) or change in redox potential are available outputs. To sense heat, the static properties (deflection position) or dynamic properties (frequency of vibration, amplitude of vibration, etc.) can be measured.

Redox changes are especially interesting because these can be used to alter the voltage (charge) of the charged element, and therefore produce an output dependent on a modulated charge. Redox changes may also alter electrical conductivity, and other properties. For example, a redox change may be measured with a colorimetric redox indicator, which can interact with an optical system, such as a laser or light emitting diode (semiconductor or organic semiconductor). The result can be a change in temperature. However, in a pulse illumination system, the coupling of the charged element to the pulse may vary depending on its optical absorption, and therefore a dynamic response without significant change in bulk temperature may be measured.

In some cases, the sensor may provide fluidic sensing. Typically, the presence of a liquid between the sensing electrodes and the charge element is problematic, since many liquids are conductive and will bleed the charge on the charged element, though some liquids are dielectric and non-conductive. However, considering aqueous solutions and biological analytes, these are typically contraindicated for the space in which the relevant electrical field is to be sensed, and even a high humidity in this region may be problematic for reliable sensing. One solution is to fabricate a sensor which operates at <1.23 V (hydrolysis potential of water), and provide a current supply to the charged element that replenishes the drained charge. Note that this sensor may act as a conductive sensor, in which current flow split between the electrodes is dependent on position. However, in some cases, the attractive force between the electrode and charged element may still be relevant, since regardless of current flow, the force is dependent on the charge and distance.

An alternate is to provide an analyte in a fluid space with a wall, and have the charged element mounted outside of the fluid space on the opposite side of the wall. Changes in the fluid space that alter electrical or thermodynamic factors may be sensed through the wall, and reflected in a change in electrical (charge) or mechanical property of the charged element(s). For example, a glucose sensor may be implemented by an immobilized glucose oxidase enzyme in a fluid space. Glucose oxidase catalyzes the conversion of glucose to gluconolactone, FAD is reduced to FADH₂, which is oxidized back to FAD by a redox mediator, which is then oxidized by an electrode reaction. (Of course, this potential may be measured directly). The electrode, in this case is coupled to the charged element, and the charge on the charged element is dependent on the glucose oxidation. If the charged element is induced to move, the amplitude of the signal will be dependent on the charge induced on the charged element by the glucose oxidation. Other enzyme-coupled reactions may be similarly sensed. One advantage of this embodiment is that it achieves electrical isolation of the aqueous medium and the electronics. Another advantage is that it is potentially responsive to intervening conditions and superposed effects. For example, if two enzymes engage in competing or parallel reactions, outputs of their reaction can sum or difference.

The charged element may be induced to motion directly by a sensed effect, or coupled with another mechanical element and indirectly induced to move. Likewise, a modulation of motion by a sensed effect may be a direct effect of the sensing interaction, or indirectly through an intervening element.

An imaging sensor, e.g., a spatial array of elements whose displacement or vibration is modulated by illumination by ultraviolet, visible, infrared, far infrared, terahertz radiation, etc., and an optical system which projects an image on the array for sensing, may be implemented. Long wavelength sensing, which is relatively difficult with semiconductor CCD or photodiode imagers, are particularly attractive applications. It is noted that the sensing electrodes are designed to have an electrical field which is aligned with the elongated axis of the moving element over its range of movement, so that a pull-in effect is avoided; however, this can be implemented to permit a “back side” illumination, i.e., the image is projected onto the array (or single element sensor) through the electrode side of the device. Vibration of the moving elements may be induced by providing a time-varying electrical field around the moving element, for example my modulating the sensing electrodes or providing an additional “drive” electrode system. In any case, where the electric field is modulated, the electronics would generally filter or compensate for the modulation, while demodulating the imposed signal.

A system employing the sensor may be a cellphone (smartphone) or other consumer electronic device, automobile or component thereof, flying object or drone, telephone, computer, display device, military munition, toy, or the like. The sensor can replace traditional types of capacitive sensors in a variety of applications, and the advantages permit new applications.

Various sensors which may be modified to employ the present technology, and uses of such sensors are known. See, U.S. Pat. Nos. 6,199,575; 6,621,134; 6,670,809; 6,749,568; 6,848,317; 6,889,555; 6,926,670; 6,935,165; 6,994,672; 7,036,372; 7,046,002; 7,073,397; 7,077,010; 7,078,796; 7,093,494; 7,109,859; 7,143,652; 7,164,117; 7,169,106; 7,204,162; 7,205,173; 7,260,980; 7,260,993; 7,340,941; 7,368,312; 7,397,421; 7,402,449; 7,425,749; 7,451,647; 7,474,872; 7,518,493; 7,518,504; 7,539,532; 7,539,533; 7,543,502; 7,558,622; 7,562,573; 7,663,502; 7,677,099; 7,689,159; 7,694,346; 7,732,302; 7,733,224; 7,748,272; 7,775,215; 7,775,966; 7,784,344; 7,786,738; 7,795,695; 7,810,394; 7,849,745; 7,878,075; 7,915,891; 7,923,999; 7,950,281; 7,977,635; 7,984,648; 8,000,789; 8,016,744; 8,020,440; 8,037,757; 8,061,201; 8,103,333; 8,108,036; 8,118,751; 8,121,673; 8,121,687; 8,129,802; 8,130,986; 8,136,385; 8,143,576; 8,146,424; 8,171,794; 8,187,795; 8,215,168; 8,235,055; 8,268,630; 8,278,919; 8,323,188; 8,323,189; 8,328,718; 8,338,896; 8,344,322; 8,347,717; 8,352,030; 8,368,154; 8,371,166; 8,390,916; 8,397,579; 8,418,556; 8,425,415; 8,427,177; 8,434,160; 8,434,161; 8,449,471; 8,461,988; 8,464,571; 8,467,133; 8,472,120; 8,475,368; 8,477,425; 8,477,983; 8,482,859; 8,488,246; 8,500,636; 8,516,905; 8,525,673; 8,525,687; 8,531,291; 8,534,127; 8,542,365; 8,578,775; 8,615,374; 8,646,308; 8,652,038; 8,669,814; 8,677,821; 8,680,991; 8,684,253; 8,684,900; 8,684,922; 8,708,903; 8,713,711; 8,717,046; 8,719,960; 8,727,978; 8,742,944; 8,747,313; 8,747,336; 8,750,971; 8,764,651; 8,787,600; 8,814,691; 8,831,705; 8,833,171; 8,833,175; 8,845,557; 8,848,197; 8,850,893; 8,875,578; 8,878,528; 8,924,166; 8,939,154; 8,963,262; 8,964,298; 8,968,195; 9,000,833; 9,007,119; 9,020,766; 9,028,405; 9,034,764; 9,046,547; 9,052,194; 9,052,335; 9,060,683; 9,074,985; 9,086,302; 9,094,027; 9,096,424; 9,097,890; 9,097,891; 9,107,586; 9,118,338; 9,128,136; 9,128,281; 9,129,295; 9,134,534; 9,151,723; 9,159,710; 9,182,596; 9,190,937; 9,194,704; 9,199,201; 9,204,796; 9,215,980; 9,222,867; 9,223,134; 9,228,916; 9,229,227; 9,237,211; 9,238,580; 9,250,113; 9,252,707; 9,285,589; 9,291,638; 9,307,319; 9,322,685; 9,329,689; 9,335,271; 9,341,843; 9,351,640; 9,359,188; 9,364,362; 9,366,862; 9,389,077; 9,389,215; 9,400,233; 9,404,954; 9,423,254; 9,441,940; 9,444,404; 9,459,100; 9,459,673; 9,465,064; 9,473,831; 9,476,975; 9,494,477; 9,518,886; 9,522,276; 9,528,831; 9,534,974; 9,541,464; 9,549,691; 9,557,345; 9,568,461; 9,575,089; 9,582,072; 9,584,931; 9,588,190; 9,596,988; 9,628,919; 9,631,996; 9,644,963; 9,651,538; 9,658,179; 9,683,844; 9,689,889; 9,695,038; 9,696,222; 9,708,176; 9,722,561; 9,733,230; 9,733,268; 9,759,917; 9,775,520; 9,778,302; 9,781,521; 9,801,542; 9,814,425; 9,820,657; 9,820,658; 9,835,647; 9,838,767; 9,839,103; 9,843,858; 9,843,862; 9,844,335; 9,846,097; 9,856,133; 9,863,769; 9,865,176; 9,866,066; 9,867,263; 9,875,406; 9,897,460; 9,897,504; 9,901,252; 9,903,718; 9,907,473; 9,910,061; 9,910,062; 9,938,133; 9,945,746; 9,945,884; 9,958,348; 9,970,958; 9,976,924; 20020151816; 20020177768; 20020193674; 20040007051; 20040119591; 20040207808; 20040260470; 20050001316; 20050001324; 20050046584; 20050066728; 20050072231; 20050104207; 20050139871; 20050199071; 20050199072; 20050265124; 20060056860; 20060081054; 20060081057; 20060107768; 20060178586; 20060205106; 20060208169; 20060211912; 20060211913; 20060211914; 20060248950; 20070023851; 20070029629; 20070089512; 20070089513; 20070125161; 20070129623; 20070209437; 20070230721; 20070241635; 20070265533; 20070273504; 20070276270; 20080001735; 20080004904; 20080021336; 20080079444; 20080081958; 20080149832; 20080163687; 20080169921; 20080188059; 20080202237; 20080281212; 20080294019; 20090022505; 20090024042; 20090049911; 20090064781; 20090064785; 20090072840; 20090078044; 20090114016; 20090133508; 20090140356; 20090227876; 20090227877; 20090255336; 20090282916; 20090318779; 20090320591; 20100039106; 20100049063; 20100083756; 20100100079; 20100132466; 20100147073; 20100186510; 20100238454; 20100242606; 20100244160; 20100251800; 20100271003; 20100275675; 20100308690; 20110010107; 20110049653; 20110061460; 20110062956; 20110073447; 20110089324; 20110100126; 20110115624; 20110120221; 20110138902; 20110181422; 20110192226; 20110192229; 20110226065; 20110254107; 20110267212; 20110295270; 20110317245; 20120004564; 20120025277; 20120032286; 20120034954; 20120043203; 20120075168; 20120092156; 20120092157; 20120095352; 20120095357; 20120133245; 20120192647; 20120194418; 20120194419; 20120194420; 20120194549; 20120194550; 20120194551; 20120194552; 20120194553; 20120200488; 20120200499; 20120200601; 20120206134; 20120206322; 20120206323; 20120206334; 20120206335; 20120206485; 20120212398; 20120212399; 20120212400; 20120212406; 20120212414; 20120212484; 20120212499; 20120218172; 20120218301; 20120235847; 20120235883; 20120235884; 20120235885; 20120235886; 20120235887; 20120235900; 20120235969; 20120236030; 20120236031; 20120242501; 20120242678; 20120242697; 20120242698; 20120245464; 20120249797; 20120291549; 20120313711; 20120330109; 20130002244; 20130009783; 20130023794; 20130023795; 20130047746; 20130050155; 20130050226; 20130050227; 20130050228; 20130069780; 20130072807; 20130080085; 20130095459; 20130104656; 20130127980; 20130133396; 20130156615; 20130170681; 20130172691; 20130172869; 20130178718; 20130186171; 20130191513; 20130197322; 20130201316; 20130204488; 20130211291; 20130215931; 20130221457; 20130226034; 20130226035; 20130226036; 20130231574; 20130263665; 20130276510; 20130278631; 20130279717; 20130297330; 20130314303; 20130317753; 20130328109; 20130330232; 20130340524; 20140011697; 20140026686; 20140031263; 20140041452; 20140047921; 20140049256; 20140053651; 20140055284; 20140063054; 20140063055; 20140077946; 20140090469; 20140094715; 20140104059; 20140111019; 20140111154; 20140121476; 20140130587; 20140142398; 20140143064; 20140163425; 20140176251; 20140188404; 20140188407; 20140192061; 20140192836; 20140194702; 20140217929; 20140225250; 20140235965; 20140249429; 20140250969; 20140253219; 20140257141; 20140260608; 20140266065; 20140266263; 20140266787; 20140296687; 20140299949; 20140306623; 20140319630; 20140321682; 20140330256; 20140352446; 20150019135; 20150068069; 20150082872; 20150096377; 20150099941; 20150105631; 20150125003; 20150125832; 20150126900; 20150141772; 20150154364; 20150163568; 20150171885; 20150176992; 20150211853; 20150220199; 20150226558; 20150250393; 20150260751; 20150268060; 20150268284; 20150269825; 20150276529; 20150309316; 20150309563; 20150323466; 20150323560; 20150323694; 20150338217; 20150351648; 20150359467; 20150374378; 20150377662; 20150377916; 20150377917; 20150377918; 20160000431; 20160000437; 20160002026; 20160003698; 20160006414; 20160030683; 20160041211; 20160066788; 20160076962; 20160130133; 20160131480; 20160137486; 20160139173; 20160140834; 20160161256; 20160176704; 20160187654; 20160202755; 20160209648; 20160213934; 20160223579; 20160231792; 20160232807; 20160235494; 20160241961; 20160274141; 20160287166; 20160305780; 20160305835; 20160305838; 20160305997; 20160310020; 20160320426; 20160327446; 20160327523; 20160334439; 20160338644; 20160341761; 20160347605; 20160349056; 20160360304; 20160360965; 20160363575; 20160370362; 20160377569; 20170003314; 20170023429; 20170025904; 20170041708; 20170051884; 20170052083; 20170074853; 20170078400; 20170086281; 20170086672; 20170121173; 20170135633; 20170142525; 20170146364; 20170152135; 20170160308; 20170164878; 20170167945; 20170167946; 20170168084; 20170168085; 20170168566; 20170191894; 20170199035; 20170201192; 20170217765; 20170223450; 20170254831; 20170257093; 20170258386; 20170258585; 20170260044; 20170265287; 20170284882; 20170295434; 20170297895; 20170318385; 20170318393; 20170331899; 20170336205; 20170343350; 20170344114; 20170347886; 20180000545; 20180002162; 20180008356; 20180008357; 20180017385; 20180034912; 20180035206; 20180035228; 20180035229; 20180035888; 20180038746; 20180080954; 20180085605; 20180086625; 20180092313; 20180108440; 20180124181; 20180124521; and 20180134544, each of which is expressly incorporated herein by reference in its entirety.

The moving element may be used in an actuation mode, for example to define a carrier excitation upon which a sensed effect is modulated, either by altering an amplitude of a defined frequency, or altering a frequency or time delay (phase) characteristic. This is especially useful to move a baseband (DC) signal into a range in which the sensor displays better properties, such as higher sensitivity, lower noise, etc.

The intentional movement of the moving element, by altering the electric field surrounding it, may be used for various purposes. In one case, a pull-in response may be desired to protect the sensor from hostile environmental conditions, and therefore the moving element intentionally displaced out of harm's way. In another case, the space in which the moving element is operating may be inhomogeneous, and the movement of the moving element allows exploration of the space.

As noted above, the sensor may be highly directional, and for example have a cardioid response pattern. By deflecting the moving element from its nominal position, information regarding the vector direction of an effect may be determined. Further, this deflection can then distinguish between excitation having directional components, and excitation or noise which is non-directional. The deflection need not be binary, and in the case of a fiber sensor, can sense two axes, using 3 or more electrodes. Other configurations with larger numbers of electrodes are possible. For example, instead of having the elongated axis of the moving element directed to a gap between electrodes (the nominal design in a two-electrode, symmetric sensor), a third electrode disposed between two lateral electrodes may smooth a gradient (i.e., linearize the transition, and therefore the response of the moving electrode)) when the two lateral electrodes are maintained at different potentials, and the central electrode is maintained at an intermediate potential.

The moving element may act as a valve or flow-control vane, for a medium surrounding the element, having a position controlled by the potentials on the electrodes.

In media where the fluid is near a turbulent flow threshold, the position of one or more elements

Deflection of the moving element, especially significant deflection, can alter an effective stiffness of the sensor, which can alter both the amplitude of a response, and a resonant frequency. Each of these may be useful in various types of sensors.

### BRIEF DESCRIPTION OF THE DRAWINGS

FIGS. 1A-1D show conventional capacitive sensing schemes.

FIG. 2 shows a compliant electrostatic sensor.

FIG. 3 shows a photograph of the physical setup according to FIG. 2.

FIGS. 4A-4C show estimated first and second derivatives of the potential energy and charge sensitivity as a function of the tip displacement of the moving electrode for the electrode configuration of FIG. 2.

FIG. 5 shows a schematic representation for the characterization setup.

FIGS. 6A-6D shows measured results for the electrode configuration of FIG. 2.

FIGS. 7A-7B show measured results versus frequency for the electrode configuration of FIG. 2.

FIG. 8A shows a perforated plate diaphragm embodiment of the invention.

FIG. 8B shows a fiber mesh moving element embodiment of the invention.

### DETAILED DESCRIPTION OF THE PREFERRED EMBODIMENTS

FIG. 2 shows a compliant electrostatic sensor according to the present technology.

The moving electrode according to a preferred embodiment examined herein is composed of a thin sheet of material that is extremely flexible in the direction normal to its plane surface. It is supported along one edge so that it can rotate or bend easily about that supporting line as illustrated in FIG. 2. The figure represents a two-dimensional cross section of the system which is unchanged throughout the dimension that is perpendicular to this section. The moving electrode consists of a thin flexible element of length L₂ and thickness H₂ shown deflected relative to the horizontal orientation by the angle α. The moving electrode is shown as a straight solid body that pivots about its attachment point. It could also consist of a flexible beam or string hung at one end having small enough bending stiffness that it is free to rotate in a manner similar to that shown in FIG. 2.

The fixed electrodes are oriented so that they create plane surfaces that are orthogonal to the plane of the moving electrode. Orienting the fixed and moving electrodes so that their surfaces are orthogonal helps to minimize the net electrostatic force on the moving electrode because the electric field will always be normal to the surface of the conductors. With proper arrangement of the positions and orientations of these electrodes, one can cause the electrostatic forces acting on the plane surfaces of the moving electrode to effectively cancel, leaving the comparatively small force that is applied normal to the free edge.

According to an exemplary embodiment, the moving electrode consists of a thin flexible element of length L₂=6.2 mm and thickness H₂=5 μm shown deflected relative to the horizontal orientation by the angle α. Two vertical, fixed electrodes of length L₁=L₃=2.5 mm and thickness H₁=H₃=200 μm are shown to the right of the moving electrode. The horizontal gap between the moving electrode and the two fixed electrodes is g=300 μm. They are separated by a gap in the vertical direction of g_{y}=50 μm and are held at the same potential.

Sensing the position of the moving electrode is achieved by dividing the fixed electrode into two surfaces, denoted by electrodes 1 and 3, which are both held at the same voltage. The charge on these two fixed electrodes will vary with the moving electrode's position. For electrodes having practical dimensions, it is found that the electrostatic forces can be made to be negligible in comparison to those associated with the electrode's elastic properties.

The two vertical, fixed electrodes of length L₁ and L₃ and thicknesses H₁ and H₃ are shown to the right of the moving electrode in FIG. 2. As the moving electrode rotates, it changes the charge distribution and net capacitance on this set of electrodes. The voltage applied to the moving electrode will be set by a voltage source, V₂. The two fixed electrodes will be set at a voltage of V=0. In this example, to simplify our calculations we will assume that the moving electrode maintains the shape of a straight line so that it moves as a rigid pendulum that is free to pivot about its attachment point. Small deviations from this straight line shape due to bending will not significantly change the results. The length L₂=6.2 mm and thickness H₂=5 μm of the moving electrode ensure that the electrode is highly compliant. Their values were chosen to correspond to the measured configuration described below.

A photograph of the fabricated device is shown in FIG. 3. The three electrodes are supported on insulating blocks that were attached to micromanipulators that allowed electrode 2 to be positioned close to the line separating electrodes 1 and 3. The distances between the electrodes and the overall dimensions were determined optically using a microscope.

To very roughly estimate the mechanical stiffness of a realizable moving electrode, the stiffness of a cantilever beam supported by a fixed boundary may be considered. Assume that this electrode is constructed of a polymer having a Young's modulus of elasticity of E=2×10⁹ N/m². In order for the electrode to be conductive, it is coated with a very thin layer of aluminum, which is taken to be thin enough to not add appreciable stiffness. Considering the force to be applied uniformly along the length, the equivalent mechanical stiffness per unit width may be approximated by k≈8EI/L^{3/2} where I=H^{3/2}/12. Since L₂=6.2×10⁻³ m and H₂=5×10⁻⁶ m, the mechanical stiffness per unit width is k≈0.7 N/m². While this is a very approximate estimate, the results below indicate that the effective stiffness due to electrostatic forces is significantly less than this mechanical stiffness, and will thus have negligible influence on the motion.

FIG. 3 shows a photograph of the physical setup used to realize the concept shown in FIG. 2. Electrodes 1 and 3 are formed using thin strips of copper tape aligned vertically near the left, free end of electrode 2. Electrode 2 is clamped at its right end. The sound field was incident as shown from a direction normal to the plane of electrode 2.

While the electrode configuration of FIG. 2 does not lend itself to analysis by simple design equations as do parallel plate capacitive sensors, it is possible to estimate the charge distribution numerically for a given set of applied electrode voltages. Here a boundary element approach is utilized, which provides a numerical solution to the following integral equation:

$$v ( \vec{r} ) = \int \frac{ρ ( \vec{r} )}{ϵ 4 π R ( \vec{r} , \vec{r} ′ )} {ds}^{′} \qquad ( 10 )$$

where

$$R ( \vec{r} , {\vec{r}}^{′} ) = \sqrt{( \vec{r} - {\vec{r}}^{′} ) \cdot ( \vec{r} - {\vec{r}}^{′} )} \qquad ( 11 )$$

is the distance between \vec{r} and \vec{r}′, which are any two points on the surface of the electrodes, v(\vec{r}) is the given surface voltage specified at each position \vec{r}, and ρ(\vec{r}) is the unknown surface charge density. ∈=8.854 pF/m is the permittivity of the medium. When the domain is two dimensional, equation (10) becomes [16]

$$v ( \vec{r} ) = - \int \frac{ρ ( \vec{r} ) log R ( \vec{r} , \vec{r} ′ )}{ϵ 2 π} {ds}^{′} \qquad ( 12 )$$

Discretizing the surface into a finite number of areas enables one to solve for the charge distribution for any given electrode geometry. Knowing the charge density for a variety of positions of the moving electrode enables the calculation of the electrostatic potential energy as a function of the electrode position. These data may then be numerically differentiated to estimate the first and second derivatives which provide the electrostatic force and effective stiffness associated with the given motion.

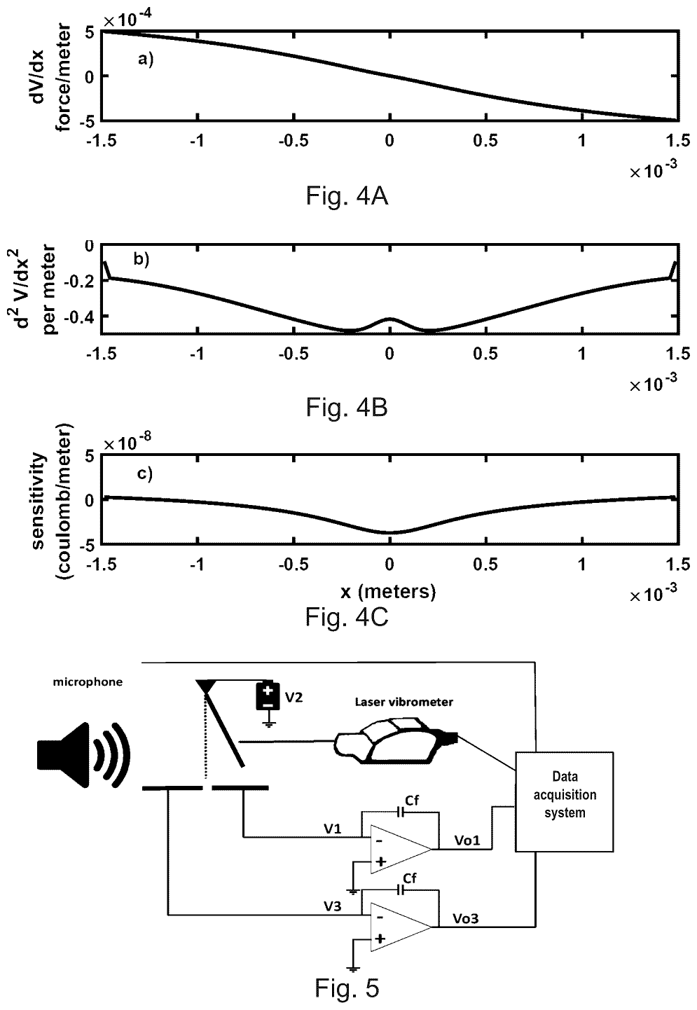

FIGS. 4A-4C show the estimated first and second derivatives of the potential energy as a function of the tip displacement of the moving electrode for the electrode configuration of FIG. 2. The effective electrostatic force is proportional to the first derivative of the potential energy shown in FIG. 4A and the electrostatic stiffness is proportional to the negative of the second derivative shown in FIG. 4B. The estimated force is always attractive and stiffening since it always acts to return the electrode to the equilibrium position at x=0. It is assumed that the bias voltage applied to the moving electrode is V=400 volts and the two fixed electrodes are at zero volts. The maximum magnitude of the charge sensitivity shown in FIG. 4C is approximately 4×10⁻⁸ coulombs/meter.

Because the domain is taken to be two dimensional, the results are for a unit length in the direction normal to the plane of FIG. 2. FIG. 2 shows that the force is always attractive, restoring the electrode to its single equilibrium position at x=0. The second derivative of the electrostatic energy provides the effective electrostatic stiffness at the equilibrium position. This electrostatic stiffness can be compared to an estimate of the mechanical stiffness of a cantilever beam as discussed above. The electrostatic stiffness is found to be approximately 0.4 N/m². The mechanical stiffness is estimated above to be k≈0.7 N/m². Note that this electrostatic stiffness is estimated with the bias applied to the moving electrode having a large value of 400 volts. This bias voltage is expected to have little noticeable effect on the electrode motion. This voltage is beyond what would be practical in a miniature microphone design. Precision microphones, however, (such as the Bruel and Kjaer 4138 used below) commonly employ a 200-volt bias. The use of this rather extreme voltage provides evidence that this electrode design is not adversely impacted by bias voltages likely to be used in practice.

The total charge Qᵢ, for i=1, 2, 3, on each of the three electrodes can be computed knowing the charge density ρ on all surfaces, Sᵢ,

$${Q}_{i} = {\int }_{{S}_{i}} ρ ( \vec{r} ) {ds}^{′} \qquad ( 13 )$$

The output of the sensor will be taken to be the difference in charge between electrodes 1 and 3.

FIG. 4C shows the predicted charge sensitivity of the device which is computed knowing the difference Q₁−Q₃ for a range of displacements of the moving electrode 2.

The derivative of this charge difference with respect to the displacement of the tip of electrode 2 is then computed, giving the sensitivity in coulombs/meter as shown in FIG. 4C.

The overall sensor sensitivity can be expressed as a combination of the charge sensitivity, denoted by S_{Q} in coulombs/meter, the electrical sensitivity, Sₑ in volts/coulomb, and the mechanical sensitivity Sₘ in meters/pascal. The over-all sensitivity will then be:

$$S = {S}_{Q} \times {S}_{e} \times {S}_{m} volt / pascal \qquad ( 14 )$$

In the experimental results presented below, a transimpedance, or charge amplifier is used to obtain an electronic output. This is accomplished using a general purpose operational amplifier where the gain is set primarily through the effective feedback capacitance C_{f}. The electrical sensitivity may then be approximated by:

$${S}_{e} \approx \frac{1}{{C}_{f}} volt / coulomb \qquad ( 15 )$$

The mechanical sensitivity, Sₘ will, of course, depend on the mechanical properties of the moving electrode 2. As a rough approximation, in a hypothetical ‘ideal’ sensor, the average motion of electrode 2 is sought to be very nearly the same as that of the air in a sound field, such as what has been demonstrated in [3]. Taking the sound field to consist of a plane wave traveling in one direction, the acoustic particle velocity is given by U=P/(ρ₀c), where ρ₀ is the nominal air density and c is the speed of propagation of an acoustic wave. The quantity ρ₀c is the characteristic acoustic impedance of the medium [17]. Because the electrode is assumed to rotate about its fixed end, the free end, where the sensing occurs, will move with approximately twice the average displacement, which will occur at the center. For a harmonic wave at the frequency ω, the mechanical sensitivity of the displacement of the free end of the electrode in this idealized case can then be approximated by:

$${S}_{m} \approx \frac{2}{{ωρ}_{0} c} meter / pascal \qquad ( 16 )$$

To obtain experimental results for the electrode system of FIG. 2, a 5 μm thick polyethylene terephthalate film, metallized with a thin layer of aluminum was used to create electrode 2 (Goodfellow.com part No. ES301855). The fixed electrodes 1 and 3 were constructed using two strips of 2.5 mm wide copper tape. The assembly was supported on micromanipulators to enable adjustment of the nominal position of the moving electrode relative to the fixed electrodes. The moving electrode was driven acoustically by a loudspeaker placed roughly 1 meter away. Measurements were performed in an anechoic chamber. FIG. 5 shows a schematic representation for the characterization setup.

An electronic output was obtained through the use of transimpedance circuits connected to electrodes 1 and 3. These circuits were not optimized for performance and used a general purpose TL074 quad operational amplifier using 1 GΩ feedback resistors. Note that the impedance of such high-value resistors is often significantly influenced by parasitic capacitance, typically on the order of C_{f}=1 pF, in parallel with the resistor, which can dominate the impedance over a wide range of frequencies. The circuit was realized using through-hole components on a prototype circuit board, which can also influence the parasitic capacitance.

FIG. 5 shows a schematic representation for the characterization setup. The electrode motion was detected using a laser vibrometer. The sound field created by a loudspeaker was measured using a Bruel and Kjaer 4138 reference microphone. The electronic output was measured using charge/transimpedance amplifiers. All signals were recorded using a National Instruments PXI-1033 Data Acquisition System.

The velocity of the moving electrode was also measured using a Polytec laser vibrometer consisting of a Polytec OFV-534 compact sensor head and a Polytec OFV-5000 Vibrometer Controller. The sound pressure near the moving electrode was measured using a Bruel and Kjaer 4138 precision microphone having a ⅛-inch diameter pressure sensing diaphragm. A bias voltage of V₂=400 volts was applied to electrode 2 using a M5-1000 DC-DC converter from American Power Designs.

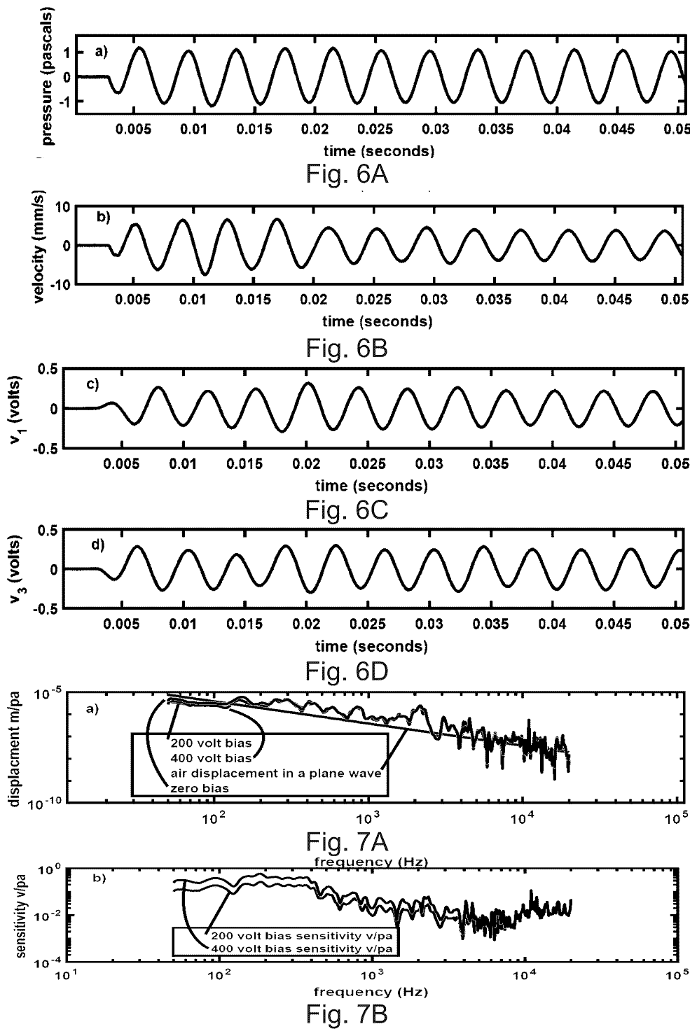

FIGS. 6A-6D show the measured results for the electrode configuration of FIG. 2. The bias voltage applied to the moving electrode is V=400 volts and the two fixed electrodes are at zero volts. The moving electrode was driven by a sound field consisting of a 250 Hz tone produced by a loudspeaker having an amplitude of approximately 1 pascal. FIG. 6A shows the measured sound pressure (pascals) at the location of the moving electrode as measured by a Bruel and Kjaer 4138 reference microphone. FIG. 6B shows the measured velocity (mm/s) halfway between the clamped and free ends of the moving electrode as obtained using a laser vibrometer. The velocity is nearly proportional to, and in phase with the pressure as occurs when the sound field propagates as a plane wave. This design may be employed using the beam response above its first resonant frequency. Because the beam is then ‘highly-compliant’ i.e., mass-dominated, as opposed to stiffness-dominated, the beam velocity is expected to be in-phase with the acoustic velocity.

FIGS. 6C and 6D show the output voltages produced by the detection circuits, employing simple transimpedance amplifiers, that respond to the charge on electrodes 1 and 3. These signals are seen to be roughly out of phase with each other as would be expected given that, when the moving electrode moves toward one of the fixed electrodes, it moves away from the other. One could then subtract the two outputs to obtain an improved detection with increased sensitivity. The output voltages have an amplitude of approximately 250 mV so that the difference output would have a sensitivity of approximately 0.5 volts/pascal. The DC bias voltage applied to electrode 2 is 400 volts for the data shown in FIGS. 6A-6D.

The displacement corresponding to the velocity shown in FIGS. 6A-6D is approximately 2.5 microns for a sound pressure of approximately 1 pascal. Note that this displacement is measured at a point halfway between the clamped and free ends of the electrode. We can then estimate that the displacement of the free end will be approximately 5 microns for a 1 pascal sound field. The effective mechanical sensitivity may then be taken to be Sₘ≈5×10⁻⁶ meter/pascal. This measured result can be compared to the rough estimate provided in equation (16) where ρ_{c}≈415 pascal-second/meter and ω=2π250. Equation (16) then gives Sₘ≈3×10⁻⁶ meter/pascal, in reasonable agreement with the measured result.

The estimated charge sensitivity shown in FIG. 4C is about S_{Q}≈40 nanoCoulombs/meter. The electrical sensitivity given in equation (15) depends on the effective capacitance, C_{f}, which as mentioned above, is estimated to be Cf≈1 pF. The terms in equation (14) are evaluated:

$$S = {S}_{Q} \times {S}_{e} \times {S}_{m} \approx ( 40 \times {10}^{- 9} ) \times {10}^{12} \times 3 \times {10}^{- 6} \approx 0.12 volt / pascal \qquad ( 17 )$$

The measured electrical output can be taken to be the difference in the signals shown in FIGS. 6C and 6D would give a measured signal having a peak voltage of about 0.5 volts for a 1 pascal sound field, which is greater than but within reasonable proximity to the rough approximation of 0.12 volts.

The data in FIGS. 6A-6D show that the sensor is capable of producing a sizable electronic output due to acoustic excitation. This is due to the use of a generous bias voltage applied to the moving electrode of 400 volts. The use of such a large bias voltage on a highly compliant electrode could normally be expected to have a marked influence on its motion.

FIGS. 7A and 7B show measured results versus frequency for the electrode configuration of FIG. 2. These results show that the bias voltage has negligible effect on the motion of the electrode while the electrical sensitivity is roughly proportional to the bias voltage over a wide range of frequencies per FIG. 7A. The measured electrode displacement amplitude as a function of frequency is independent of bias voltage for bias voltages of zero, 200 volts, and 400 volts. Also shown is the predicted air displacement amplitude for a 1 pascal plane sound wave. This shows that the electrode moves at least as much as the air in a plane wave, per FIG. 7B. The electrical sensitivity is taken to be the difference in output voltages obtained from electrodes 1 and 3 relative to the amplitude of the sound pressure at the moving electrode. This shows that the sensitivity roughly doubles for a doubling of the bias voltage, as expected.

In spite of the use of a rather large bias voltage, the results shown in FIGS. 7A-7B indicate that the electric field does not result in stiffening (or softening) of the motion of the moving electrode. The figure shows the measured electrode displacement amplitude as a function of frequency (FIG. 7A) along with the measured electrical sensitivity, defined as the difference in the output voltages acquired from electrodes 1 and 3 (shown in FIG. 2) relative to the incident sound pressure (FIG. 7B). Results are shown for bias voltages of zero, 200 volts, and 400 volts. While the response as a function of frequency is not ideal (i.e. not flat) owing to the effects of sound reflections from the fixture and from resonances of the moving electrode, it is clear that the measured electrode velocity is essentially unaffected by significant changes in the bias voltage. This indicates that the electrostatic force is negligible relative to other mechanical forces acting on the electrode, as expected from the data of FIGS. 4A-4C.

FIGS. 7A-7B also show the predicted amplitude of the fluctuating air displacement in a plane wave sound field. This indicates that the measured electrode displacement due to sound is generally higher than predicted for a plane sound wave. This also suggests that the electrode is highly compliant and its motion is unencumbered by either electrostatic or mechanical forces or stiffness.

The observation that this thin electrode can move with a displacement that is similar to that of the air in a sound field is in line with what is predicted for the sound-induced motion of a thin, flexible wall [18]. While numerous additional effects influence the motion of the electrode examined here and it does not closely resemble the problem of predicting sound transmission through walls, it is clear that a thin, lightweight membrane can move with the air in a sound field. If we consider the incident sound to be a harmonic wave at the frequency ω, propagating normal to the plane of the membrane, one can calculate the ratio of the complex amplitude of the sound wave transmitted through the membrane, pₜ to that of the incident pressure, p₁ [18],

$$\frac{{p}_{t}}{{p}_{1}} = \frac{1}{1 + \frac{\hat{i} {ρ}_{w} h ω}{2 {ρ}_{0} c}} \qquad ( 18 )$$

where ρ_{w} is the mass density of the membrane material, h is its thickness, ρ₀c≈415 pascal-s/m is the product of the nominal air density ρ₀ and the sound speed c. In a plane sound wave the ratio of the pressure to the acoustic particle velocity is equal to ρ₀c This leads to:

$${u}_{1} = \frac{{p}_{1}}{{ρ}_{0} c} , {u}_{w} = \frac{{p}_{t}}{{ρ}_{0} c} \qquad ( 19 )$$

where u₁ is the complex amplitude of the acoustic particle velocity of the incident plane wave. Equations (18) and (19) give the ratio of the membrane velocity relative to the velocity of the acoustic medium if the membrane weren't present,

$$\frac{{U}_{w}}{{U}_{1}} = \frac{1}{1 + \frac{\hat{i} {ρ}_{w} h ω}{2 {ρ}_{0} c}} \qquad ( 20 )$$

Because both velocities U_{w} and U₁ are related to the corresponding displacements by the same factor îω, the ratio in equation (20) will also equal the ratio of the displacements. This ratio depends only on the factor, (ρ_{w}hω/2ρ₀c). For the metalized polymer electrode used here, the density is estimated to be ρ_{w}≈1380 kg/m³ and the thickness is h≈5 μm. Over the range of frequencies shown in FIGS. 7A-7B, this factor varies from approximately 0.003 at 50 Hz to unity at 20 KHz. Over this range of frequencies, it is thus plausible that this thin electrode can move with a displacement that is similar to that of the air in a sound field.

The fact that the electrode is highly compliant is, of course, a major reason that its motion is easily detected by this capacitive sensing scheme. The use of a highly compliant electrode can be effective as long as the sensing configuration does not itself introduce significant electrostatic forces that would affect the motion.

The measured electrical sensitivity is shown in FIG. 7B. Again, the frequency response is not ideal due to mechanical resonances but the sensitivity is in the range between 0.1 and 1 volt/pascal over the lower frequency range shown. An optimized electrode design and a more refined readout circuit would doubtless provide improved results over these measurements.

Comparing FIGS. 7A and 7B shows that an increase in the bias voltage increases the sensitivity at nearly all frequencies in proportion to the bias voltage change while having no noticeable effect on the measured motion. The electrode configuration examined here thus achieves a decoupling of the sensing approach from the mechanical design of the electrode; one does not need to design the electrode so that it will withstand the forces applied by the electric field. The designer is free to construct as compliant a moving electrode as desired to achieve a given sensitivity without concerns that the electrostatic forces will cause instability or will impede the motion.

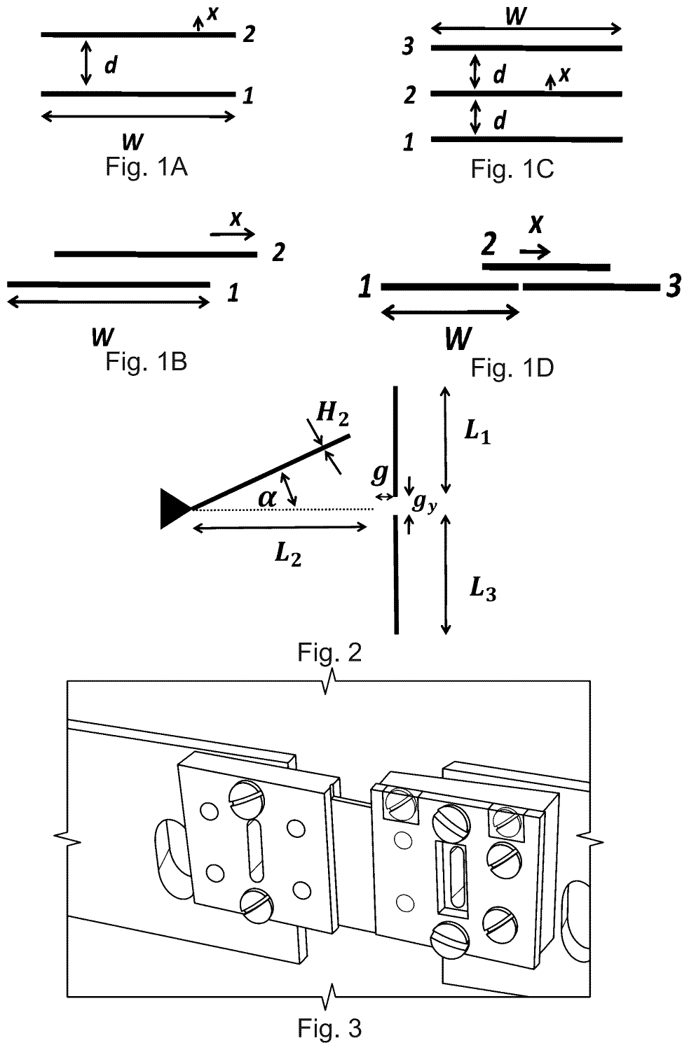

In the foregoing, it has been assumed that the moving electrode consists of a flat planar member. However, in some cases, it may be beneficial that its free edge be curved. Further, the plane of the moving member could also be oriented so that it is not parallel to the gap between the fixed electrodes. In this case, motion of the electrode will result in its overlap area with one of the fixed electrodes to increase while the overlap area with the other fixed electrode decreases. This would cause it to function much like the embodiment shown in FIG. 1D, in which the charge on the fixed electrodes depends on overlap area rather than distance as in FIG. 1C. In this case, however, the overlap area is formed by only the free edge of the moving electrode rather than its planar surfaces. The motion occurs in a direction that is generally orthogonal to the fixed electrodes rather than parallel as shown in FIG. 1D. As in the other situation previously described, large motion causes a reduced force back to the equilibrium position, causing the system to be globally stable. One could achieve this effect also by using a flat, planar moving electrode and making the gap between the fixed electrodes not parallel to it or not straight in the direction normal to the plane of FIG. 2.

Reviewing FIG. 3, the free end of the prototype embodiment of electrode 2 is not perfectly straight. This may contribute to the lack of electrostatic stiffness seen in the data.

There are numerous sensing applications where it is very desirable that the moving element is driven with diminutive forces and must therefore be as lightweight and compliant as possible so that it provides the least possible resistance and subsequently responds with the largest possible displacement. In cases where the moving element is an electrode in a capacitive sensor, care must be taken to ensure that the forces associated with the electric field do not adversely affect the motion and subsequent sensor performance. The present electrode geometries minimize the electrostatic forces that act in the direction of motion.

In the electrode design examined here, the electrostatic potential energy is considered as a function of the electrode motion. If the potential energy is roughly constant as the electrode moves, the force will tend to be small since, for this conservative force, the force is equal to the derivative of the potential energy. By splitting the fixed electrode into two elements, one can retain the insensitivity of the potential energy to the electrode displacement while enabling one to sense the differences in charge on the two fixed electrodes. The result is an ability to sense the motion without imposing significant electrostatic forces that affect the motion.

In addition to designing the sensor to maintain a nearly constant potential energy for the range of motion of interest, because the electric field is orthogonal to the surface of a conductor, the fact that the moving electrode is thin and oriented orthogonally to the fixed electrodes causes the force between them to be small. By maintaining geometric symmetry about the nominal position of the moving electrode, the electrostatic forces applied normal to its surface will approximately cancel. This enables the design of moving electrodes having altogether negligible mechanical stiffness in their primary direction of motion. A negligible stiffness can be achieved by supporting the moving electrode by a hinge that has virtually no resistance to rotation or by making the moving electrode out of an extremely thin material that has negligible resistance to bending. If the material is thin enough, one could configure it to resemble a cantilevered beam, which is fully-fixed to the supporting structure and free at its other end. The mechanical restoring stiffness need only be sufficient to resist any other environmental forces that may act on it, such as gravity.

Because electrostatic forces don't affect the motion, the bias voltage applied to the moving electrode can be set to a high value which improves the overall electrical sensitivity. In the results provided here, a highly compliant moving electrode is used that readily moves in response to acoustic pressure. The electrode configuration enables the use of a relatively large bias voltage of 400 volts while having negligible effect on the electrode motion. This produces an output electrical sensitivity of approximately 0.5 volts/pascal.

Another desirable characteristic of the capacitive sensor is the assurance of stability for the entire range of possible motions and bias voltages. As shown in FIGS. 4A-4C, when the moving electrode undergoes large motions, the restoring force will always act to return it to the equilibrium position, ensuring global stability, despite having very small resistance to small excursions from the equilibrium position.

The motion of the moving electrode is essentially unaffected by changes in the bias voltage while the overall electrical output sensitivity to sound is increased as expected.

The sensor may be designed as a microphone which achieves an equivalent acoustic pressure noise floor of 20 dBA, with a frequency response will be flat±3 decibels over the frequency range of 20 Hz to 20 KHz.

While a cantilevered plate-shaped element has been described above as the transducing element for the acoustic waves in air to mechanical motion of a charge, it is also possible to employ one or more fibers, which have the advantage of a high aerodynamic drag to mass ratio. According to the present technology, since the electrostatic interaction of the sensing plates and the moving element does not substantially deflect the element nor materially alter its stiffness, the technology permits sensing of the approximate particle motion in the air surrounding the fiber by viscous drag, as compared to the pressure difference induced deflection of a plate as is more typically measured. Further, the sensor is not limited to a single fiber, and therefore a plurality of fibers may be provided, either as independently moving parallel elements each interacting with the sensing electrodes, or formed into a loose mat or mesh, so that all fibers move together. See, [4, 30, 41, 42, 3]. For example, the fibers may be spider silk coated with 80 nm gold, or electro spun poly methyl methacrylate.

The operation of a viscous drag moving element can be analyzed based on differences in pressure from a plane traveling acoustic wave acting on its two plane surfaces. One may construct an approximate, qualitative model by considering the moving element to be an elastic beam. Focusing attention on response at a single frequency, ω, the beam deflection at a point along its length x, at time t, w(x, t), may be calculated by solving the following standard partial differential equation,

$$EI \frac{{\partial }^{4} w}{\partial {x}^{4}} + pbh \ddot{w} = P ( {e}^{\hat{i} ω t / 2} - {e}^{\hat{i} ω t / 2} ) {be}^{\hat{i} ω t} + C ( {Ue}^{\hat{i} ω t} - \dot{w} ) \qquad ( 21 )$$

where E is Young's modulus of elasticity, I is the area moment of inertia, ρ is the density of the material, b is the width, h is the thickness, P is the plane wave sound pressure amplitude, k=ω/c is the wave number with c being the wave propagation speed, dis the effective distance that sound would travel between the two plane surfaces of the beam, and Cis a viscous damping coefficient. U is the complex amplitude of the acoustic particle velocity.

As the beam becomes sufficiently thin (i.e., as h and b become small), all of the terms in equation (21) become negligible in comparison to the viscous damping force, C(Ue^{îωt}−\dot{w}) [4] because C has a very much weaker dependence on hand b than all other terms. In addition, for an isolated fiber or beam, the effective separation distance d is approximately equal to b so the acoustic pressure difference term, the first term on the right hand side, also becomes small. Consequently, in this limiting case where the viscous term dominates, the relative motion between the fiber and the air becomes negligible leading to \dot{w}≈Ue^{îωt} [4]. Therefore, with suitable design of the sensing element so that viscous forces dominate, the sensing element will move with the acoustic medium.

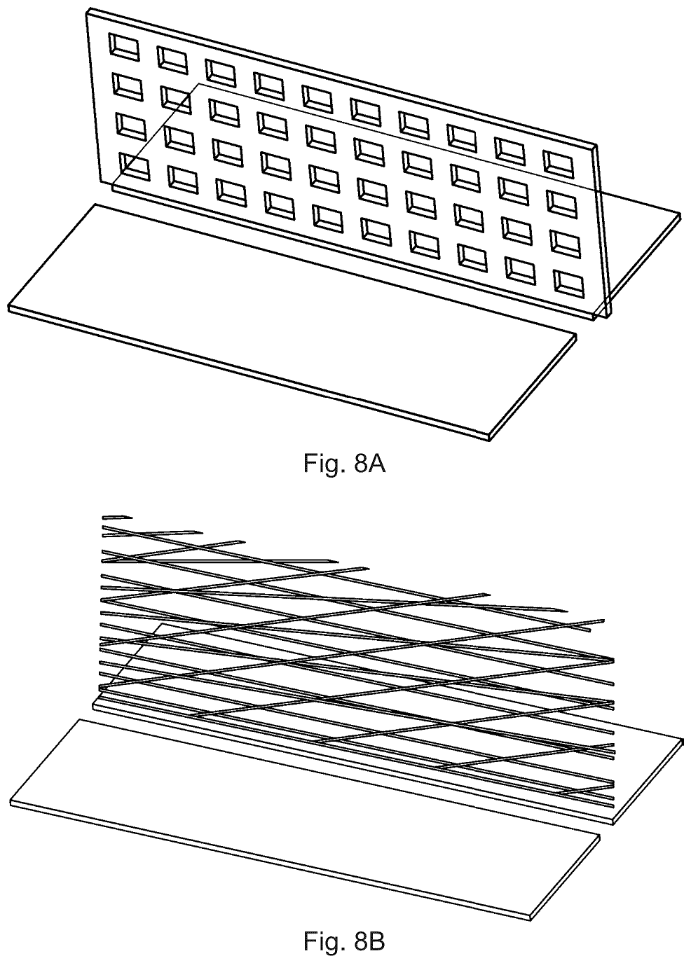

Extremely thin, compliant materials are widely available for constructing these sensing electrodes, such as graphene [1, 2], and carbon nanotubes or nanotube yarn. Flow sensing has also been accomplished with electrospun polymer fibers [41]. These very thin structures have such low bending stiffness, however, that it is not possible to incorporate them into conventional capacitive microphone designs without having their motion be strongly influenced by the electrostatic forces which occur normal to their long axis. FIG. 8A shows a planar diaphragm having an array of apertures. This design senses drag of moving air through the diaphragm, but such a design has a significant stiffness, and therefore a presumption that all terms of equation (21) are fully dominated by the viscous drag term is not generally satisfied. In some cases, however, a perforated diaphragm represents an acceptable sensor. In one example, a diaphragm may be formed of multilayer graphene. This diaphragm may also be formed of polycrystalline silicon or silicon nitride in a microelectromechanical system (MEMS) design. The diaphragm may be intrinsically conductive or metallized, such as with a layer of gold. The diaphragm, or more generally the moving element, may be formed of an electret material.

A typical silicon microfabrication process to create the thin velocity-sensing film begins with a bare silicon wafer on which a one-micron oxide is grown through wet oxidation. This oxide film provides an etch stop for a through wafer etch used to create an open air space behind the film. A silicon nitride film having thickness approximately 0.5 micron is then deposited using a low pressure chemical vapor deposition (LPCVD) furnace. The silicon nitride is patterned through optical lithography to define the holes to achieve porosity and to define the electrode edges. Portions of the nitride film are made to be conductive by depositing and patterning a thin (approximately 80 nm) layer of phosphorous doped silicon using a LPCVD process. The film is then annealed to form polycrystalline silicon. A through-wafer backside reactive ion etch (RIE) is performed to expose the backside of the silicon electrode. The electrode is released by removing the thermal oxide, using buffered hydrofluoric acid. The fabrication of the sensing electrodes is performed by depositing conductive films around the perimeter of the moving electrode.

FIG. 8B shows a fiber mesh element which forms a loose plate which generally moves as a unit by viscous drag of moving air against the fibers. The mesh is designed to have high stiffness due to forces applied in the plane of the mesh while having high compliance when out of plane forces (such as those due to the acoustic flow) are applied. Because the mesh consists of a large number of loosely arranged individual fibers, dimensional precision and in-plane stiffness at the edge nearest the sensing electrodes is difficult to assure if the fibers in proximity to the sensing electrodes are free. This, in turn, impairs repeatable sensitivity and resistance to in-plane electrostatic attractive forces. Therefore, a thin solid frame or binding may be provided attached to the mesh at the edge nearest the sensing electrodes. Suitable fibers include metallized electrospun PMMA and carbon nanotubes, or both in combination.

The fibers may be less and 1μ, and for example may be about 500 nm diameter.

The device according to the present technology may be used not only as a sensor, but also as an actuator. In this case, for example, we may apply a small time-varying differential voltage to electrodes which will effectively modulate the system's equilibrium position about a null position. A voltage applied to the moving element electrode may be set to a value that adjusts the electrostatic stiffness to nearly any value desired, leaving the motion to be limited only by the mechanical stiffness and mass of the moving electrode.

The use of an extremely compliant and lightweight moving electrode material, such as for example, graphene, would enable actuation with very small driving voltage. This configuration permits a wide range of adjustment of the equilibrium position as a function of small changes in the driving voltage. The response of the moving electrode to changes in voltage is linear, instead of quadratic, as might otherwise be expected for a parallel plate actuator. Further, in a 4-electrode embodiment which has three static electrodes instead of two as described above, may also be used. In this case, the additional electrode provides additional ability to adjust the effective electrostatic stiffness of the moving electrode. Note that the forces may be repulsive rather than attractive as discussed in various embodiments above.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

### REFERENCES

Each of the following is expressly incorporated herein by reference in its entirety:
[1] Y.-M. Chen, S.-M. He, C.-H. Huang, C.-C. Huang, W.-P. Shih, C.-L. Chu, J. Kong, J. Li, and C.-Y. Su, “Ultra-large suspended graphene as a highly elastic membrane for capacitive pressure sensors,” Nanoscale, vol. 8, no. 6, pp. 3555-3564, 2016.
[2] C. Berger, R. Phillips, A. Centeno, A. Zurutuza, and A. Vijayaraghavan, “Capacitive pressure sensing with suspended graphene-polymer heterostructure membranes,” Nanoscale, vol. 9, no. 44, pp. 17439-17449, 2017.
[3] J. Zhou and R. N. Miles, “Sensing fluctuating airflow with spider silk,” Proceedings of the National Academy of Sciences, p. 201710559, 2017.
[4] R. Miles and J. Zhou, “Sound-induced motion of a nanoscale fiber,” Journal of Vibration and Acoustics, vol. 140, no. 1, p. 011009, 2018.
[5] R. Miles and F. Degertekin, “Optical sensing in a directional mems microphone,” Nov. 2, 2010, U.S. Pat. No. 7,826,629.
[6] B. Bicen, S. Jolly, K. Jeelani, C. T. Garcia, N. A. Hall, F. L. Degertekin, Q. Su, W. Cui, and R. N. Miles, “Integrated Optical Displacement Detection and Electrostatic Actuation for Directional Optical Microphones With Micromachined Biomimetic Diaphragms,” IEEE Sensors Journal, vol. 9, no. 12, pp. 1933-1941 December 2009.
[7] R. N. Miles, Q. Su, W. Cui, M. Shetye, F. L. Degertekin, B. Bicen, C. Garcia, S. Jones, and N. Hall, “A low-noise differential microphone inspired by the ears of the parasitoid fly Ormia ochracea,” Journal of the Acoustical Society of America, vol. 125, no. 4, Part 1, pp. 2013-226 April 2009.
[8] M. L. Kuntzman, N. N. Hewa-Kasakarage, A. Rocha, D. Kim, and N. A. Hall, “Micromachined in-plane pressure-gradient piezoelectric microphones,” IEEE Sensors Journal, vol. 15, no. 3, pp. 1347-1357, 2015.
[9] B.-H. Kim and H.-S. Lee, “Acoustical-thermal noise in a capacitive mems microphone,” IEEE Sensors Journal, vol. 15, no. 12, pp. 6853-6860, 2015.
[10] L. K. Baxter, “Capacitive sensors,” Ann Arbor, vol. 1001, p. 48109, 2000.
[11] D. K. Miu, Mechatronics: electromechanics and contromechanics. Springer Science & Business Media, 2012.
[12] R. Miles, “Comb sense microphone,” Jun. 9, 2009, U.S. Pat. No. 7,545,945.
[13] R. N. Miles, W. Cui, Q. T. Su, and D. Homentcovschi, “A mems low-noise sound pressure gradient microphone with capacitive sensing,” Journal of Microelectromechanical Systems, vol. 24, no. 1, pp. 241-248, 2015.
[14] S. Towfighian, S. He, and R. B. Mrad, “A low voltage electrostatic micro actuator for large out-of-plane displacement,” in ASME 2014 International Design Engineering Technical Conferences and Computers and Information in Engineering Conference, American Society of Mechanical Engineers, 2014, pp. V004T09A015-V004T09A015.
[15] S. He, R. B. Mrad, and J. Chang, “Development of a high-performance microelectrostatic repulsive-force rotation actuator,” Journal of Microelectromechanical Systems, vol. 19, no. 3, pp. 561-569, 2010.
[16] D. Poljak and C. A. Brebbia, Boundary element methods for electrical engineers. WIT Press, 2005, vol. 4.
[17] P. Morse and K. Ingard, Theoretical Acoustics. Princeton Univ Pr, 1986.
[18] A. London, “Transmission of reverberant sound through single walls,” J. Research Nat. Bur. of Stand, vol. 42, no. 605, p. 2, 1949.
[19] R. N. Miles, W. Cui, Q. T. Su, and D. Homentcovschi, “A mems low-noise sound pressure gradient microphone with capacitive sensing,” Journal of Microelectromechanical Systems, vol. 24, no. 1, pp. 241-248, 2015.
[20] T. T. Bringley. Analysis of the immersed boundary method for Stokes flow. PhD thesis, New York University, 2008.
[21] K. K. Charaziak and C. A. Shera. Compensating for ear-canal acoustics when measuring otoacoustic emissions. The Journal of the Acoustical Society of America, 141(1):515-531, 2017.
[22] R. Cox. The motion of long slender bodies in a viscous fluid part 1. general theory. Journal of Fluid mechanics, 44(4):791-810, 1970.
[13] W. Cui, B. Bicen, N. Hall, S. Jones, F. Degertekin, and R. Miles. Optical sensing in a directional MEMS microphone inspired by the ears of the parasitoid fly, Ormia ochracea. In MEMS 2006: 19th IEEE International Conference on Micro Electro Mechanical Systems, Technical Digest, Proceedings: IEEE Micro Electro Mechanical Systems Workshop, pages 614-617, 2006., Istanbul, TURKEY, Jan. 22-26, 2006.
[24] H. Droogendijk, J. Casas, T. Steinmann, and G. Krijnen. Performance assessment of bio-inspired systems: flow sensing mems hairs. Bioinspiration & biomimetics, 10(1):016001, 2014.
[25] T. Götz. Interactions of fibers and flow: asymptotics, theory and numerics. PhD thesis, Technical University of Kaiserslautern, 2000.
[26] K. Grosh and R. J. Littrell. Piezoelectric mems microphone, Dec. 26, 2017. U.S. Pat. No. 9,853,201.
[27] D. Homentcovschi, R. Miles, P. Loeppert, and A. Zuckerwar. A microacoustic analysis including viscosity and thermal conductivity to model the effect of the protective cap on the acoustic response of a mems microphone. Microsystem technologies, 20(2):265-272, 2014.
[27] W.-X. Huang, S. J. Shin, and H. J. Sung. Simulation of flexible filaments in a uniform flow by the immersed boundary method. Journal of Computational Physics, 226(2):2206-2228, 2007.
[28] G. Kämper and H.-U. Kleindienst. Oscillation of cricket sensory hairs in a low-frequency sound field. Journal of Comparative Physiology A, 167(2):193-200, 1990.
[29] R. Miles. Comb sense capacitive microphone, Jun. 9, 2009. US Patent App. 2009/0262958.
[30] R. N. Miles. “A Compliant Capacitive Sensor for Acoustics: Avoiding Electrostatic Forces at High Bias Voltages.” IEEE Sensors Journal 18, no. 14(2018):5691-5698.
[31] C. Motchenbacher and J. Connelly. Low-Noise Electronic System Design. John Wiley & Sons, Inc., 1993.
[32] L. Rosenhead. Laminar Boundary Layers: An Account of the Development, Structure, and Stability of Laminar Boundary Layers in Incompressible Fluids, Together with a Description of the Associated Experimental Techniques. Clarendon Press, 1963.
[33] M. J. Shelley and T. Ueda. The stokesian hydrodynamics of flexing, stretching filaments. Physica D: Nonlinear Phenomena, 146(1):221-245, 2000.
[34] R. Sisto, L. Cerini, F. Sanjust, and A. Moleti. Intensimetric detection of distortion product otoacoustic emissions with ear canal calibration. The Journal of the Acoustical Society of America, 142(1):EL13-EL17, 2017.
[35] G. G. Stokes. On the effect of the internal friction of fluids on the motion of pendulums, volume 9. Pitt Press, 1851.
[36] A.-K. Tornberg and K. Gustavsson. A numerical method for simulations of rigid fiber suspensions. Journal of Computational Physics, 215(1):172-196, 2006.
[37] A.-K. Tornberg and M. J. Shelley. Simulating the dynamics and interactions of flexible fibers in stokes flows. Journal of Computational Physics, 196(1):8-40, 2004.
[38] S. Towfighian and R. N. Miles. A new approach to capacitive sensing: Repulsive sensors, Sep. 1, 2016. NSF Grant 1608692.
[39] B. Varanda, R. Miles, and D. Warren. Characterization of the dominant structural vibration of hearing aid receivers. Journal of Vibration and Acoustics, 138(6):061009, 2016.
[40] E. Wente. A condenser transmitter as a uniformly sensitive instrument for the absolute measurement of sound intensity. Physical Review, 10(1):39, 1917.
[41] J. Zhou, B. Li, J. Liu, W. Jones Jr., and R. Miles. Highly-damped nanofiber mesh for ultrasensitive broadband acoustic flow detection, 2018. to appear Journal of Micromechanics and Microengineering.
[42] J. Zhou and R. Miles. Directional sound detection by sensing acoustic flow, 2018. to appear IEEE Sensors.
[43] J. M. Crowley, Fundamentals of applied electrostatics. John Wiley & Sons, 1986.
[44] N. Jonassen, Electrostatics. Springer Science & Business Media, 2013.
[45] T. F. Eibert and V. Hansen, “On the calculation of potential integrals for linear source distributions on triangular domains,” IEEE Transactions on Antennas and Propagation, vol. 43, no. 12, pp. 1499-1502, 1995.
[46] J. Zhou, R. N. Miles, and S. Towfighian, “A novel capacitive sensing principle for microdevices,” in ASME 2015 International Design Engineering Technical Conferences and Computers and Information in Engineering Conference. American Society of Mechanical Engineers, 2015, pp. V004T09A024-V004T09A024.

What is claimed is:

1. A microphone comprising:
two conductors spaced apart from one another by a gap, the gap being defined by a spacing between respective edges of the two conductors, each conductor of the two conductors having a planar surface that terminates at the edge;
a displaceable electrode configured for movement relative to the two conductors; and
a circuit configured to produce an output signal corresponding to the movement based on a change in capacitance between the two conductors and the displaceable electrode;
wherein:
the displaceable electrode has a thickness such that the displaceable electrode is compliant to facilitate the movement; and
the displaceable electrode has an equilibrium position in which the displaceable electrode is oriented such that the thickness of the displaceable electrode is defined in a direction parallel to the planar surfaces of the two conductors.

2. The microphone of claim 1, wherein the displaceable electrode is planar.

3. The microphone of claim 1, wherein, in the equilibrium position, the displaceable electrode is oriented in a plane orthogonal to the planar surfaces of the two conductors.

4. The microphone of claim 1, wherein the displaceable electrode is positioned and oriented relative to the two conductors such that an electrostatic force arising from a bias voltage between the two conductors and the displaceable electrode acts as a restoring force to return the displaceable electrode to the equilibrium position.

5. The microphone of claim 1, further comprising a further conductor disposed between the two conductors.

6. The microphone of claim 5, wherein:
the two conductors are biased at different voltages relative to the displaceable electrode; and
the further conductor is biased at an intermediate potential between the different voltages.

7. The microphone of claim 5, wherein:
the two conductors are biased such that a net electrostatic force is an attractive force on the displaceable electrode; and
the further conductor is biased to establish a repulsive force on the displaceable electrode.

8. The microphone of claim 1, wherein the displaceable electrode comprises a hinge.

9. The microphone of claim 1, wherein the displaceable electrode comprises a planar diaphragm.

10. The microphone of claim 1, wherein the planar surfaces of the two conductors are coplanar such that the respective edges of the two conductors are aligned with one another.

11. The microphone of claim 1, wherein the thickness of the displaceable electrode is positioned in the gap when the displaceable electrode is in the equilibrium position.

12. The microphone of claim 1, wherein the displaceable electrode does not overlap either of the two conductors when the displaceable electrode is in the equilibrium position.

13. The microphone of claim 1, further comprising a voltage source configured to apply a bias voltage to the displaceable electrode.

14. The microphone of claim 1, wherein the circuit comprises an amplifier.

15. The microphone of claim 14, wherein the amplifier is connected to the two conductors.

16. The microphone of claim 1, wherein the movement is in parallel with the planar surfaces of the two conductors.

17. The microphone of claim 1, wherein the displaceable electrode comprises a perforated plate.

18. The microphone of claim 1, wherein each of the two conductors is fixed.

19. The microphone of claim 1, wherein the two conductors are grounded.

20. The microphone of claim 1, wherein the two conductors are biased at different voltages relative to the displaceable electrode.
